(19) United States
(12) Patent Application Publication
(10) Pub. No.: US 2007/0063639 A1
(43) Pub. Date: Mar. 22, 2007

(54) ORGANIC ELECTROLUMINESCENCE ELEMENT, EXPOSURE DEVICE AND IMAGE FORMING

(75) Inventors: Takafumi Hamano, Osaka (JP); Shinya Yamamoto, Osaka (JP)

Correspondence Address: GREENBLUM & BERNSTEIN, P.L.C., 1950 ROLAND CLARKE PLACE, RESTON, VA, 20191, US

(73) Assignee: MATSUSHITA ELECTRIC INDUSTRIAL CO., LTD., Osaka (JP)

(21) Appl. No.: 11/461,040

(22) Filed: Jul. 31, 2006

(30) Foreign Application Priority Data
Jul. 29, 2005 (JP) 2005-219979

(51) Int. Cl. H01J 1/62; H01J 63/04

(52) U.S. Cl. 313/504

(57) ABSTRACT

In an organic electroluminescence element, a stray light which is confined in the inside of a light emitting layer, an anode and a glass substrate receives the conversion of angle at an end portion of a pixel restricting portion and is eradiated and hence, a substantial light emitting region is expanded from an original light emitting region. When such an organic electroluminescence element is used in an exposure device, the resolution is substantially lowered. To overcome such a drawback, the present invention provides an organic electroluminescence element includes an anode to which holes are injected, a light emitting layer, a cathode to which electrons are injected, and a pixel restricting portion which restricts a light emitting region of the light emitting layer by controlling the injection of at least one of the holes and the electrons, wherein a thickness of an end portion of the pixel restricting portion on a side thereof which restricts the light emitting region is set to a value equal to or more than 20 nm and equal to or less than 100 nm.

### BACKGROUND OF THE INVENTION

1. Field of the Invention

The present invention relates to an organic electroluminescence element, an exposure device which uses the organic electroluminescence elements in a row thus forming an exposure light source, and an image forming apparatus which mounts the exposure device thereon.

2. Description of the Related Art

The electroluminescence element is a light emitting device which makes use of an electric field light emission of a solid fluorescent material. Currently, an inorganic electroluminescence element which uses an inorganic material as a light emitting body has been put into practice and the inorganic electroluminescence element has been partially applied to a backlight of a liquid crystal display or a flat display. However, a voltage which is required to make the inorganic electroluminescence element emit light is high, that is, 100V or more and, further, it is difficult for the inorganic electroluminescence element to provide blue light emission and hence, it is difficult to realize a full color display using three primary colors of R, G, B. Further, in the inorganic electroluminescence element, a material which is used as a light emitting body exhibits an extremely large reflectance and hence, the light emitting body is strongly influenced by a total reflection on an interface or the like whereby a pickup efficiency of light with respect to an actual light emission into air is low, that is, 10 to 20% thus making the inorganic electroluminescence element difficult to emit light with high efficiency.

On the other hand, attentions have been focused on studies on an electroluminescence element which uses an organic material for many years and various reviews have been made. However, due to the extremely poor light emitting efficiency the full-scale studies on the practical use of the electroluminescence element have not progressed.

However, in 1987, C. W. Tang et al of Kodak Corporation proposed an organic electroluminescence element having the function-separation type stacked structure which separates an organic material which forms a light emitting layer into a hole transporting layer and a light emitting layer. This proposal revealed that it is possible to obtain the high light emission brightness of 1000 cd/cm² or more in spite of a low voltage of 10V or less (see C. W. Tang, S. A. Vanslyke, “Applied Physics Letter” (United States of America), Vol 51, 1987, p 913.). Since then, the organic electroluminescence element has attracted attentions suddenly and even, at present, studies on the organic electroluminescence element having the function-separation type stacked structure have been extensively made. Particularly, the higher efficiency and the prolonged lifetime which are prerequisites for the practical use of the organic electroluminescence element having the function-separation type stacked structure have been sufficiently studied and a display or the like which uses the organic electroluminescence element has been realized.

FIG. 12 is a cross-sectional view showing the structure of a conventional organic electroluminescence element.

Hereinafter, the structure of the conventional general organic electroluminescence element is explained in conjunction with FIG. 12.

As shown in FIG. 12, the organic electroluminescence element 11 includes an anode 13 made of a transparent conductive film such as an ITO film having a thickness of 100 nm to 500 nm which is formed, for example, on a glass substrate 12 by sputtering method, a resistance heating and vapor-deposition method or the like, a hole transporting layer 14 made of N,N′-diphenyl-N,N′-bis(3-methylphenyl)-1,1′-diphenyl-4,4′-diamin (hereinafter abbreviated as TPD) or the like, an organic material layer 15 made of 8-Hydroxyquinoline Aluminum (hereinafter abbreviated as Alq3) or the like which is formed on the hole transporting layer 14 by a resistance heating and vapor-deposition method or the like, and a cathode 17 made of a metal film having a thickness of 50 nm to 500 nm which is formed on the organic material layer 15 by a resistance heating and vapor-deposition method or the like.

Here, the hole transporting layer 14 and the organic material layer 1S are collectively and simply referred to as a light emitting layer 16 for the sake of convenience. Here, the light emitting layer 16 is formed to have a thickness of approximately 10 nm to 500 nm. The light emitting layer 16 may include, besides the hole transporting layer 14 and the organic material layer 15, a hole injecting layer, an electron injecting layer, an electron transporting layer, an electron blocking layer (all being not omitted from drawing). The same goes for the explanation made hereinafter.

Assuming the anode 13 of the organic electroluminescence element 11 having the above-mentioned constitution as a plus electrode and the cathode 17 of the organic electroluminescence element 11 as a minus electrode, when a DC voltage or a DC current is applied to the organic electroluminescence element 11, holes are injected into the organic material layer 15 from the anode 13 via the hole transporting layer 14, and electrons are injected into the organic material layer 15 from the cathode 17. In the organic material layer 15 which constitutes the light emitting layer 16, the holes and the electrons are re-coupled and when excitons which are generated by the re-coupling are moved to a ground state from an excited state, a light emitting phenomenon is generated.

In such an organic electroluminescence element 11, light which is radiated from a phosphor in the inside of the organic material layer 15 is usually radiated in all azimuths about the phosphor and is radiated into air in the light pick-up direction (direction toward the glass substrate 12) via the hole transporting layer 14, the anode 13 and the glass substrate 12. Alternatively, the light advances in the direction opposite to the light pick-up direction once and, thereafter, is reflected on the cathode 17 and is irradiated into air via the light emitting layer 16, the anode 13 and the glass substrate 12.

Further, with respect to the conventional organic electroluminescence element 11, the structures disclosed in Japanese Patent Document 2734464, Japanese Patent Laid-open 2000-172198 are named, for example.

FIG. 13 is a cross-sectional view showing a structural example of the conventional organic electroluminescence element 11. First of all, the structure of the conventional organic electroluminescence element 11 described in Japanese Patent Document 2734464 is explained in conjunction with FIG. 13.

In FIG. 13, numeral 18 indicates a pixel restricting portion, wherein the pixel restricting portion 18 is an insulating film made of polyimide or the liken and having a thickness of 100 nm to 5 μm which is formed in contact with the anode 13. The pixel restricting portion 18 is formed as a layer. An opening is formed in an upper surface of the anode 13 by the pixel restricting portion 18 and, due to a control of the supply of a charge by the pixel restricting portion 18, only a light emitting region LA emits light out of the light emitting layer 16.

In Japanese Patent Document 2734464, by forming such a pixel restricting portion 18 on the anode 13 in this manner, it is possible to avoid the lowering of the accuracy of the formation of a pattern attributed to a turn-around of vapor deposition in manufacturing steps of the organic electroluminescence element 11. Further, by coloring the pixel restricting portion 18 with black or a deep color, a contrast of the organic electroluminescence element 11 can be enhanced and, at the same time, due to the formation of the pixel restricting portion 18 in a tapered shape at a portion thereof where the pixel restricting portion 18 and the anode 13 are in contact with each other, it is possible to prevent the electrical disconnection attributed to a stepped portion of the pixel restricting portion 18.

FIG. 14 is a cross-sectional view showing a structural example of the conventional organic electroluminescence element 11. Next, the structure of the conventional organic electroluminescence element described in Japanese Patent Laid-open 2000-172198 is explained in conjunction with FIG. 14.

In FIG. 14, the pixel restricting portion 18 is formed into a tapered shape using a resin material colored in black, for example (color resist or the like). With the provision of the pixel restricting portion 18, it is possible to prevent the light which is generated by the light emitting layer 16 from directly reaching a TFT (Thin Film Transistor) which constitutes a drive circuit not shown in the drawing thus suppressing the increase of a leak current of the TFT Although no definite description is found in Japanese Patent Laid-open 2000-172198 with respect to a thickness of the pixel restricting portion 18 (referred to as a leveling insulating film in Japanese Patent Laid-open 2000-172198), in view of the facts that the resin material such as the color resist is used, the pixel restricting portion 18 has a function of leveling the stepped portion formed by the structural body such as TFT (not shown in the drawing), it is necessary to acquire an advantageous effect to shield light and the like, the pixel restricting portion 18 may be required to have the thickness of at least approximately several micrometers.

FIG. 15 is a cross-sectional view showing a periphery of the pixel restricting portion 18 in the conventional organic electroluminescence element 11. Hereinafter, drawbacks of the conventional organic electroluminescence element 11 are explained in detail in conjunction with FIG. 15.

In the explanation made hereinafter, an end portion of the pixel restricting portion 18 on a side which restricts the light emitting region LA (indicated by P1 in FIG. 15) is referred to as an “end portion P1 of the pixel restricting portion 18” (same definition being used in the explanation made in conjunction with other drawings).

As explained previously, in the organic electroluminescence element 11, the electrons which are injected from the anode 13 and the cathode 17 are re-coupled in the light emitting layer 16 and, as the result of re-coupling, light is radiated. Accordingly, light which is radiated from the phosphor in the light emitting layer 16 is radiated in all azimuths about the phosphor, Here, a reflectance of the light emitting layer 16 is approximately 1.6, a reflectance of the anode 13 is approximately 2.0 when the anode 13 is ITO, and a reflectance of the glass substrate 12 is approximately 1.5 and hence, out of the light which is radiated from the light emitting layer 16, light having a particular angle component is totally reflected on an interface between the anode 13 and the glass substrate 12 due to the difference in reflectance between the anode 13 and the glass substrate 12, and the totally-reflected light is reflected by the cathode 17. That is, a portion of light which is generated by the light emitting layer 16 is confined between the anode 13 and the cathode 17 and becomes a so-called stray light (LO indicated in FIG. 15, for example).

Further, since a reflectance of air is 1.0, out of the light which is radiated from the light emitting layer 16, light which is incident on a light-takeout side of the glass substrate 12 at an angle which exceeds a critical angle based on the reflectance difference with the reflectance of air is totally reflected. Further, when the pixel restricting portion 18 allows the light to pass therethrough, the light passes through the pixel restricting portion 18 and is reflected on the cathode 17 which substantially constitutes a reflection film. That is, also in this case, a portion of light which is generated by the light emitting layer 16 is confined between the glass substrate 12 and the cathode 17 and becomes so-called stray lights (L1, L2 indicated in FIG. 15, for example).

Here, although the end portion P1 of the pixel restricting portion 18 makes an angle θ1 with respect to the anode 13 and the glass substrate 12, when the stray light arrives at the end portion P1 of the pixel restricting portion 18, the stray light has an angle thereof converted so that the stray light is radiated to the outside of the glass substrate 12 as indicated by LX, for example. Since the stray light exists in the inside of the light emitting layer 16, the anode 13 and the glass substrate 12 in all angles and directions equal to or more than a critical angle dependent on the reflectance between the anode 13 and the glass substrate 12 or the reflectance between the glass substrate 12 and air and hence, this phenomenon may arise basically unless the angle θ1=0. The pixel restricting portion 18 originally serves to restrict the light emitting region LA of the light emitting layer 16 so as to prevent the light from being radiated from portions other than the light emitting region LA. However, when the stray light exits, the light LX which should not be radiated originally is radiated from the end portion P1 of the pixel restricting portion 18 (hereinafter, the light which is radiated attributed to this phenomenon being referred to as “edge light”). As described above, the stray light has all angle components and hence, this phenomenon is observed even in a case that the above-mentioned angle θ1 assumes 90 degrees, that is, the end portion P1 of the pixel restricting portion 18 is perpendicular to the anode 13 (that is, the structure described in Japanese Patent Document 2734464). However, in this case, as shown in FIG. 15, the radiation angle of the edge light differs from the edge light shown in FIG. 15.

FIG. 16 is an explanatory view for showing the stray light state in which the pixel restricting portion 18 is colored (that is, the structure described in Japanese Patent Laid-open 2000-172198).

In this case, although the incident light is totally reflected at an angle which exceeds the critical angle on an interface between the anode 13 and the glass substrate 12 and on an interface between the glass substrate 12 and air, by imparting a sufficient light blocking effect (that is, sufficiently high concentration to block light) to the pixel restricting portion 18 by coloring the material of the pixel restricting portion 18 with black, for example, there is no possibility that the stray light is reflected on the end portion P1 of the pixel restricting portion 18 and is observed as the edge light LX. However, in an attempt to prevent the edge light LX at portions other than the light emitting region LA by coloring the pixel restricting portion 18, it is necessary to ensure the light blocking effect and hence, the pixel restricting portion 18 is required to have the thickness of several micrometers as mentioned previously.

Here, since the organic electroluminescence element 11 is a so-called face light source, if it is possible to make the thickness of the light emitting layer 16 uniform in a region which is sandwiched by the anode 13 and the cathode 17, that is, in a total region of the light emitting region LA restricted by the pixel restricting portion 18, the uniformity of the light emission brightness in the light emitting region LA is enhanced. However, when the conventional organic electroluminescence element 11 is formed using a process including a coating step which is represented by a spin coating method, in forming the pixel restricting portion 18 which restricts the light emitting region LA between the anode 13 and the cathode 17, when the pixel restricting portion 18 is formed in contact with the anode 13 as shown in FIG. 16, at the end portion P1 of the pixel restricting portion 18, due to the influence of a capillary phenomenon or a surface tension, in general, the thickness of the light emitting layer 16 at an end portion P1 of the pixel restricting portion (Z1 in FIG. 16) becomes larger than the thickness of the light emitting layer 16 at a center portion of the light emitting region LA. Due to the difference in current density attributed to such difference in thickness of the light emitting layer 16, the distribution of the light emission brightness in the light emitting region LA is not made uniform and, the light emission brightness of the end portion P1 of the pixel restricting portion 18 where the current density is low in general becomes low compared to the light emission brightness at the center portion of the light emitting region LA.

That is, in the above-mentioned organic electroluminescence element 11, even when the colored pixel restricting portion 18 is provided to prevent the edge light LX, the thickness of the pixel restricting portion 18 is eventually increased thus giving rise to a drawback that the light emission brightness does not become uniform in the light irradiation directions. This drawback cannot be overcome by simply forming a shape of the end portion P1 of the pixel restricting portion 18 into a tapered shape.

FIG. 17 is an explanatory view showing the distribution (in-plane distribution) of light emission brightness in the light emitting region LA of the conventional organic electroluminescence element 11. As has been explained heretofore, the distribution (in-plane distribution) of light emission brightness in the light emitting region LA of the conventional organic electroluminescence element 11, as indicated by the in-plane distribution O in FIG. 17, exhibits the light emission brightness which is lowered in the direction toward the end portion P1 of the pixel restricting portion 18 from the center portion of the light emitting region LA and, when any stray light preventing measure is not provided to the pixel restricting portion 18, possesses the distribution such that the light emission brightness becomes high outside the original light emitting region LA due to the presence of the edge light LX at the end portion P1 of the pixel restricting portion 18. That is, the distribution of light emission brightness in the individual organic electroluminescence element 11 assumes a non-uniform state.

Here, in a device which directly acts on a human vision within a clearly viewable distance such as a general display device, for example, and to which the organic electroluminescence element 11 is applied, a task to be solved lies in the realization of the light emission with uniform light quantity (total quantity) among the individual organic electroluminescence elements 11, and this task can be overcome by restricting the light emitting region LA by the isometric structure of the pixel restricting portion 18. Accordingly, the presence of the edge light LX or the uniformity of the light emission brightness in the light emitting region LA of the individual organic electroluminescence element 11 has hardly been considered as a task to be solved. However, a radiation angle and a strength of the edge light LX is influenced by a delicate angle of the pixel restricting portion 18 at the end portion P1 thereof and hence, there arises a drawback such as the irregularities in a light emission quantity also in the display device depending on the accuracy of formation of the pixel restricting portion 18.

Further, to consider an application of the organic electroluminescence element 11 as a light source of an exposure device of an image forming apparatus such as an electrophotographic apparatus, it is necessary to form an electrostatic latent image having a desired shape and a desired potential distribution per one pixel unit in the image forming apparatus and hence, the light emitting region LA of the organic electroluminescence element 11 must be equal with respect to all pixels. However, when a width of the light emitting region is substantially increased due to the edge light LX in a region other than the light emitting region LA, a size of a light spot formed on a photoconductor becomes large thus lowering the resolution.

Further, the stray light exists as components having various angles between the anode 13 and the cathode 17 as well as between the glass substrate 12 and the cathode 17, in an extreme case, there arises a phenomenon that the edge light LX is radiated from the end portion P1 of the pixel restricting portion 18 of the neighboring organic electroluminescence element 11 (not shown in the drawing). Since a portion of the organic electroluminescence element 11 which is not allowed to emit light radiates light by being influenced by the neighboring organic electroluminescence element, this phenomenon generates an optical crosstalk thus making a faithful display or image formation difficult.

Further, when the light emission brightness in the light emitting region LA of the organic electroluminescence element 11 is not uniform, that is, when a contrast region exists in the inside of the light emitting region LA of the individual organic electroluminescence element 11, in obtaining a desired exposure quantity, a relatively bright region is deteriorated earlier, Since the lifetime of the organic electroluminescence element 11 is controlled by a portion which exhibits the largest deterioration, when the light emission brightness is not uniform, compared to a case that the light emission brightness is uniform, the lifetime of the organic electroluminescence element 11 is substantially shortened.

Further, when the thickness of the light emitting layer 16 is not uniform, a current flows in a thin portion of the light emitting layer 16 in a concentrated manner and hence, the not only the light emission brightness becomes non-uniform at an initial stage of light emission but also the distribution of light emission brightness in the light emitting region LA is changed within a long period such that a dark portion becomes a relatively bright portion later due to the lowering of brightness of a portion in which a large quantity of current flows. This implies that when the organic electroluminescence element 11 is applied to an exposure device, a shape or an area of a latent image which the exposure device forms is changed with a lapse of time and it is difficult to obtain a stable image for a long period.

Further, particularly with respect to the exposure device, to cope with a shortage of exposure light quantity which induces the deterioration of the organic electroluminescence element 11, it is necessary to correct the light quantity. In a light correction step, the brightness of the organic electroluminescence element 11 is measured by a light receiving means described later, and a current value or the like which drives the organic electroluminescence element 11 is controlled based on a result of the measurement. Due to such light quantity correction, exposure light quantity of the organic electroluminescence element 11 may be recovered as a whole. However, when the degree of deterioration for every micro region of the light emitting layer 16 is different as mentioned previously, it is difficult to restore the original distribution of light emission brightness. Accordingly, even when the light quantity correction is executed, the sizes of individual pixels formed by the image forming apparatus are changed thus giving rise to a drawback such that longitudinal stripes in printing, for example, are generated.

### SUMMARY OF THE INVENTION

Accordingly, it is an object of the present invention to provide an organic electroluminescence element which possesses high uniformity in light emission brightness in the light emitting region when edge light is eliminated or even when the edge light is prevented, that is, an organic electroluminescence element which exhibits the distribution of light emission brightness indicated by an in-plane distribution N shown in FIG. 17, an exposure device which can obtain an electrostatic latent image having a desired size or shape by using such an organic electroluminescence element, and an image forming apparatus capable of forming a high quality image which mounts such an exposure device thereon.

The organic electroluminescence element of the present invention has been made to overcomes the above-mentioned drawbacks and includes an anode to which holes are injected, a light emitting layer, a cathode to which electrons are injected, and a pixel restricting portion which restricts a light emitting region of the light emitting layer by controlling the injection of at least one of the holes and the electrons, wherein a thickness of an end portion of the pixel restricting portion on a side thereof which restricts the light emitting region is set to a value equal to or more than 50 nm and equal to or less than 100 nm.

Due to such a constitution, it is possible to prevent edge light of the organic electroluminescence element and, at the same time, it is possible to make the light emission brightness in the light emitting region which is restricted by the pixel restricting portion uniform. That is, the in-plane distribution (light quantity profile) of the light emission brightness of light which is radiated from the light emitting region of individual organic electroluminescence element assumes a substantially rectangular shape and hence, an exposure device which uses the organic electroluminescence element as a light source thereof can form an electrostatic latent image having a desired shape or potential distribution whereby it is possible to realize an image forming apparatus which can form a high-quality image.

Further, the deterioration becomes uniform in all regions of the light emitting region of the individual organic electroluminescence element and hence, it is possible to substantially prolong the lifetime of the organic electroluminescence element.

Still further, since the light quantity profile has the rectangular shape, the lowering of the light emission brightness attributed to the deterioration of the light emitting region progresses uniformly whereby even when a drive current is increased to compensate for the deterioration, the shape of the in-plane distribution (light quantity profile) of the light emission brightness is not changed thus enabling the formation of the electrostatic latent image always in a stable manner.

### BRIEF DESCRIPTION OF THE DRAWINGS

FIG. 1 is an explanatory view showing a structure of an organic electroluminescence element according to an embodiment 1 of the present invention;

FIG. 2 is a constitutional view of an exposure device according to the embodiment 1;

FIG. 3(a) is a top plan view of a glass substrate of the exposure device of the embodiment 1, and FIG. 3(b) is an enlarged view of an essential part of a glass substrate of the exposure device of the embodiment 1;

FIG. 4 is a circuit diagram of the exposure device of the embodiment 1;

FIG. 5 is a cross-sectional view of the organic electroluminescence element and a drive circuit of the exposure device of the embodiment 1;

FIG. 6 is a constitutional view of an image forming device on which an exposure device to which the organic electroluminescence element of the embodiment 1 is applied is mounted;

FIG. 7 is a constitutional view showing the periphery of a developing station in the image forming device of the embodiment 1;

FIG. 8 is a cross-sectional view showing a structure of an organic electroluminescence element according to an embodiment 2;

FIG. 9(a) to FIG. 9(d) are explanatory views which illustrate shapes of end portions of a pixel restricting portion according to the embodiment 2;

FIG. 10 is a cross-sectional view showing a structure of an organic electroluminescence element according to an embodiment 3;

FIG. 11 is a cross-sectional view showing a structure of an organic electroluminescence element according to an embodiment 4;

FIG. 12 is a cross-sectional view showing a structure of a conventional organic electroluminescence element;

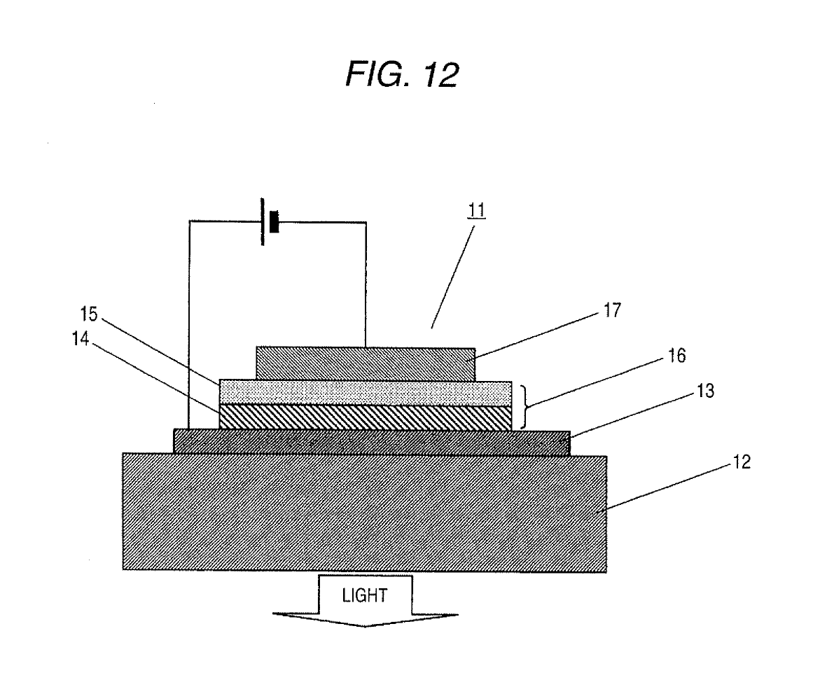

FIG. 13 is a cross-sectional view showing a structural example of a conventional organic electroluminescence element;

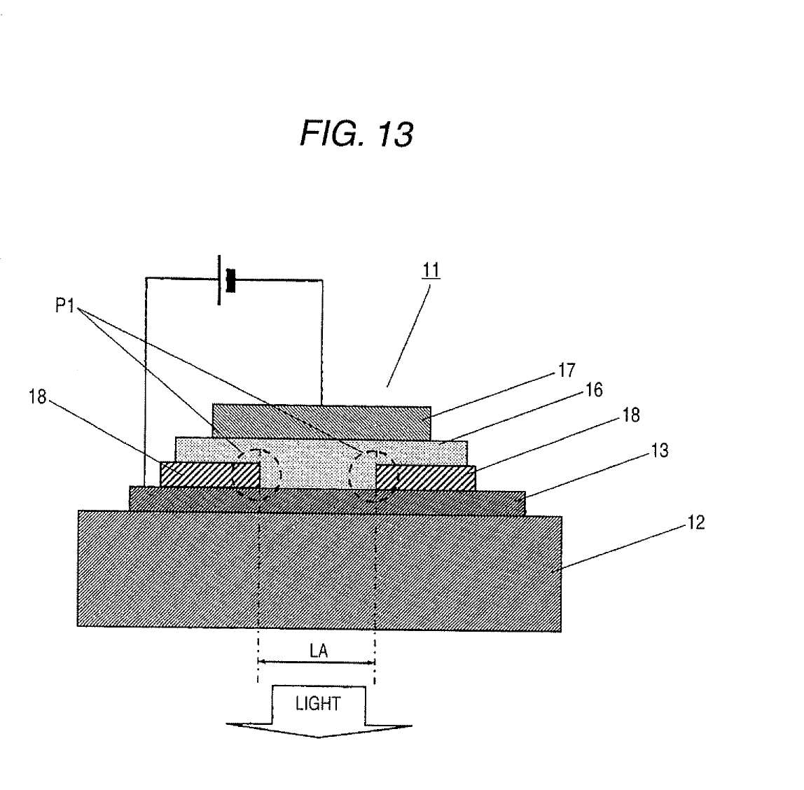

FIG. 14 is a cross-sectional view showing a structural example of a conventional organic electroluminescence element;

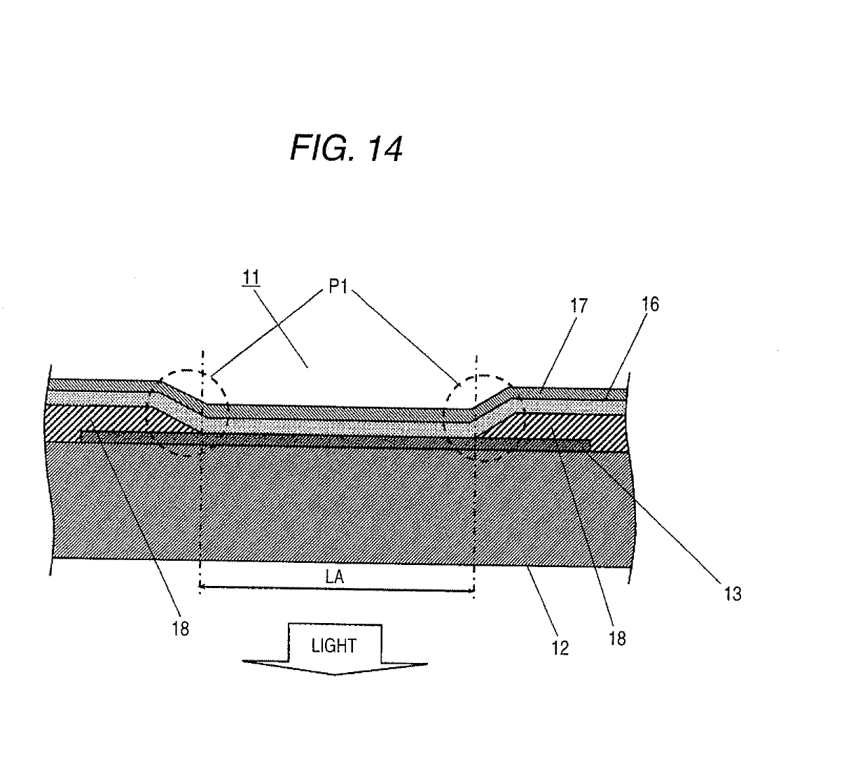

FIG. 15 is a cross-sectional view showing the periphery of a pixel restricting portion in a conventional organic electroluminescence element;

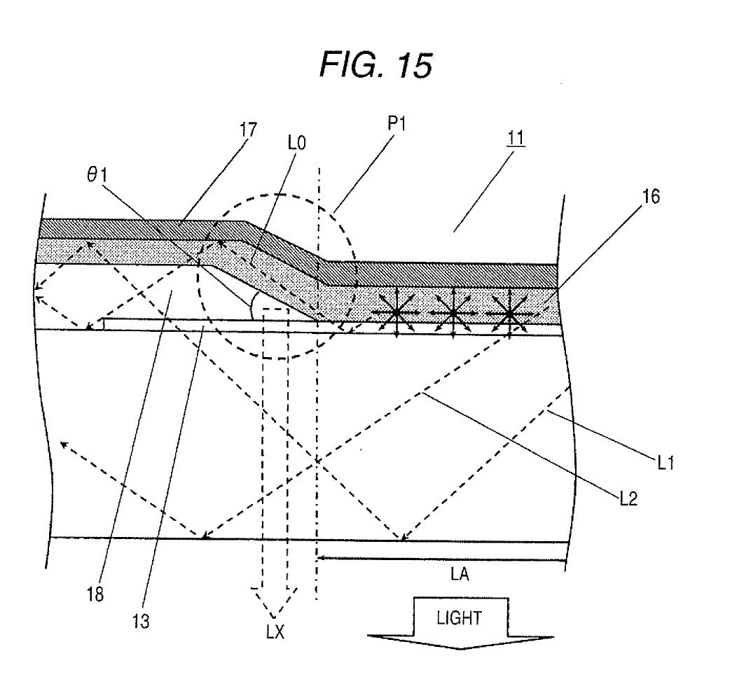

FIG. 16 is an explanatory view showing a state of stray light when the pixel restricting portion is colored; and

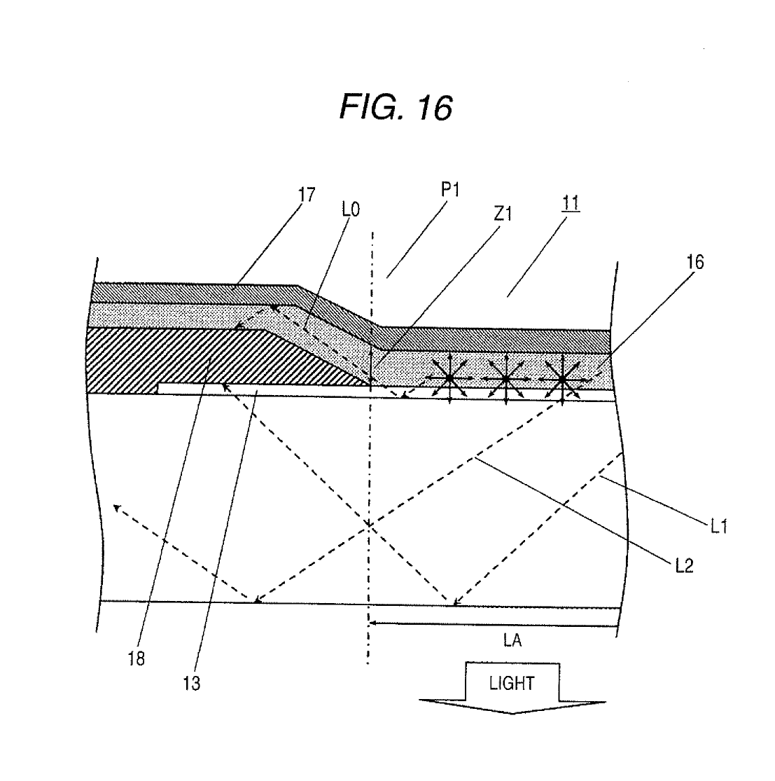

FIG. 17 is an explanatory view showing a distribution of an emission luminance in an emitting region of a conventional organic electroluminescence element.

### DESCRIPTION OF THE PREFERRED EMBODIMENTS

The organic electroluminescence element of the present invention may include an anode to which holes are injected, a light emitting layer, a cathode to which electrons are injected, and a pixel restricting portion which restricts a light emitting region of the light emitting layer by controlling the injection of at least one of the holes and the electrons, wherein a thickness of an end portion of the pixel restricting portion on a side thereof which restricts the light emitting region is set to a value equal to or more than 50 nm and equal to or less than 100 nm. Due to such a constitution, an edge light can be prevented and, at the same time, the distribution of light emission brightness (light quantity profile) of the light radiated from the light emitting region becomes uniform. Further, the distribution of an electric current which flows in the organic electroluminescence element becomes uniform and hence, the organic electroluminescence element can obtain the uniform light emission for a long period. Further, portions which are made to emit light wastefully to obtain the desired light emission brightness become no more necessary and hence, it is possible to prolong the lifetime of the organic electroluminescence element.

Further, the present invention is directed to the organic electroluminescence element which includes: an anode to which holes are injected; a light emitting layer; a cathode to which electrons are injected; and a pixel restricting portion which restricts a light emitting region of the light emitting layer by controlling the injection of at least one of the holes and the electrons, wherein a thickness of an end portion of the pixel restricting portion at least on a side which restricts the light emitting region is set to a value which equal to or more than 20 nm and equal to or less than 100 nm. Due to such a constitution, it is possible to prevent the edge light and, at the same time, it is possible to make the distribution of the light emission brightness of light which is radiated from the light emitting region (light quantity profile) uniform. Further, it is also possible to make the distribution of a current which flows in the organic electroluminescence element uniform and hence, the uniform light emission is acquired over a long period. Further, portions which wastefully emit bright light for obtaining the desired light emission brightness become no more necessary and hence, a lifetime of the organic electroluminescence element can be prolonged.

Further, in the organic electroluminescence element of the present invention, the pixel restricting portion is made of one selected from a group consisting of silicon nitride, aluminum nitride, silicon oxide and aluminum oxide. These materials are excellent in insulating property, the pixel restricting accuracy and the like and hence, even when the pixel restricting portion is made thin so as to effectively suppress the generation of an edge light, the pixel restricting portion can maintain high insulating property thus performing an original function of pixel restricting portion. Further, these materials can obtain high wettability to a solvent which dissolves a light emitting material which forms the light emitting layer with simple forming or to a solution which dissolves a light emitting material therein and hence, in forming the light emitting layer in so-called coating step, a thickness of the light emitting layer can be made uniform whereby it is possible to make the light emission brightness in the light emitting region uniform.

Further, according to the present invention, in the organic electroluminescence element, the pixel restricting portion may be made of a metal material. Due to such a constitution, it is possible to make the light transmissivity of the pixel restricting portion substantially zero and hence, it is possible to surely prevent the edge light in regions other than the light emitting region and, at the same time, a thickness of the pixel restricting portion can be reduced thus eliminating the non-uniformity of the thickness of the light emitting layer attributed to a stepped portion of the pixel restricting portion.

Further, according to the present invention, assuming a work function of the pixel restricting portion as W_{F1} and a work function of the anode as W_{F2} in the organic electroluminescence element, the pixel restricting portion may be made of a metal material in which the work function W_{F1} satisfies 2.0[eV]<W_{F1}<W_{F2}. Due to such a constitution, it is possible to make the light transmissivity of the pixel restricting portion substantially zero and hence, it is possible to surely prevent the edge light in regions other than the light emitting region and, at the same time, a thickness of the pixel restricting portion can be reduced thus eliminating the non-uniformity of the thickness of the light emitting layer attributed to a stepped portion of the pixel restricting portion.

Further, according to the present invention, in the organic electroluminescence element, the pixel restricting portion may allow a region thereof other than the end portion thereof to have a thickness larger than a thickness of the end portion. Due to such a constitution, it is possible to enhance the insulating property between the anode and the cathode.

Further, according to the present invention, in the organic electroluminescence element, the pixel restricting portion may be made of a material which prevents light having a light emitting wavelength which is emitted from the light emitting layer from passing through the pixel restricting portion. Due to such a constitution, it is possible to surely prevent the edge light in the region other than the light emitting region.

In the organic electroluminescence element of the present invention, the pixel restricting portion is formed by a sputtering method. Due to such a constitution, the pixel restricting portion can be formed using a dense film and hence, it is possible to easily form the pixel restricting portion which makes a thickness of an end portion thereof on a side which restricts the light emitting region small and, at the same time, prevents the leaking of a current. Accordingly, while preventing the edge light, it is possible to make the distribution of the light emission brightness of the light radiated from the light emitting region (light quantity profile) uniform. Further, the distribution of the current which flows in the organic electroluminescence element becomes uniform and hence, the organic electroluminescence element can obtain the uniform light emission over a long period.

Further, according to the present invention, an organic electroluminescence element may include an anode to which holes are injected, a light emitting layer, a cathode to which electrons are injected, and a pixel restricting portion which is formed of a plurality of layers and restricts a light emitting region of the light emitting layer by controlling the injection of at least one of the holes and the electrons, wherein a thickness of an end portion of the pixel restricting portion on a side thereof which restricts the light emitting region is set to a value equal to or more than 20 nm and equal to or less than 100 nm. Due to such a constitution, it is possible to prevent the edge light and, at the same time, it is possible to make the distribution of the light emission brightness (light quantity profile) of the light radiated from the light emitting region uniform and hence, the distribution of an electric current which flows in the organic electroluminescence element can be made more uniform thus realizing the acquisition of the uniform light emission over a long period. Further, portions which are made to emit light wastefully to obtain the desired light emission brightness become no more necessary and hence, it is possible to prolong the lifetime of the organic electroluminescence element.

Further, the present invention is directed to an organic electroluminescence element which includes; an anode to which holes are injected; a light emitting layer; a cathode to which electrons are injected; and a pixel restricting portion which is formed of a plurality of layers and restricts a light emitting region of the light emitting layer by controlling the injection of at least one of the holes and the electrons, wherein a thickness of an end portion of the pixel restricting portion at least on a side which restricts the light emitting region is set to a value which equal to or more than 50 nm and equal to or less than 100 nm. Due to such a constitution, it is possible to prevent the edge light and, at the same time, it is possible to make the distribution of the light emission brightness of light which is radiated from the light emitting region (light quantity profile) uniform. Further, it is also possible to make the distribution of a current which flows in the organic electroluminescence element uniform and hence, the uniform light emission is acquired over a long period. Further, portions which wastefully emit bright light for obtaining the desired light emission brightness become no more necessary and hence, a lifetime of the organic electroluminescence element can be prolonged.

Further, according to the present invention, in the organic electroluminescence element, the pixel restricting portion is constituted of a first pixel restricting portion which is formed in contact with the anode or the cathode and a second pixel restricting portion which is formed in contact with the first pixel restricting portion and covers a portion of the anode or the cathode. Due to such a constitution, functions of the pixel restricting portion are shared by two pixel restricting layers and hence, the edge light can be more surely prevented and, at the same time, the distribution of the light emission brightness of the light which is radiated from the light emitting region can be made uniform and hence, the distribution of an electric current which flows in the organic electroluminescence element can be made more uniform thus realizing the acquisition of the uniform light emission over a long period.

Further, according to the present invention, in the organic electroluminescence element, the pixel restricting portion is constituted of a second pixel restricting portion which is formed in contact with the anode or the cathode and a first pixel restricting portion which is formed in contact with the second pixel restricting portion and covers a portion of the second restricting portion. Due to such a constitution, functions of the pixel restricting portion are shared by two pixel restricting layers and hence, the edge light can be more surely prevented and, at the same time, the distribution of the light emission brightness of the light which is radiated from the light emitting region can be made uniform and hence, the distribution of an electric current which flows in the organic electroluminescence element can be made more uniform thus realizing the acquisition of the uniform light emission over a long period.

Further, in the present invention, at least one of the first pixel restricting portion and the second pixel restricting portion is made of a material which prevents at least light having a light emitting wavelength radiated from the light emitting layer from passing therethrough. Due to such a constitution, it is possible to surely prevent the edge light in the region other than the light emitting region.

Further, in the organic electroluminescence element of the present invention, at least one layer out of the pixel restricting portion which is formed of a plurality of layers is formed by a sputtering method. Due to such a constitution, the pixel restricting portion can be formed using a dense film and hence, it is possible to easily form the pixel restricting portion which makes a thickness of an end portion thereof on a side which restricts the light emitting region small and, at the same time, prevents the leaking of a current. Accordingly, while preventing the edge light, it is possible to make the distribution of the light emission brightness of the light radiated from the light emitting region (light quantity profile) uniform. Further, the distribution of the current which flows in the organic electroluminescence element becomes uniform and hence, the organic electroluminescence element can obtain the uniform light emission over a long period.

Further, the organic electroluminescence element of the present invention includes: an anode to which holes are injected; a light emitting layer; a cathode to which electrons are injected; and a pixel restricting portion which restricts a light emitting region of the light emitting layer by controlling the injection of at least one of the holes and the electrons, wherein a thickness of an end portion of the pixel restricting portion at least on a side which restricts the light emitting region is set to a value which is twice or less larger than a thickness of the light emitting layer. Due to such a constitution, while preventing the edge light, it is possible to make the distribution of the light emission brightness of the light radiated from the light emitting region (light quantity profile) uniform. Further, the distribution of the current which flows in the organic electroluminescence element becomes uniform and hence, the organic electroluminescence element can obtain the uniform light emission over a long period. Further, portions which wastefully emit bright light for obtaining the desired light emission brightness become no more necessary and hence, a lifetime of the organic electroluminescence element can be prolonged.

Further, in the organic electroluminescence element of the present invention, the thickness of the end portion of the pixel restricting portion at least on the side which restricts the light emitting region is set to a value which is twice or less larger than the thickness of the light emitting layer, and the thickness of the pixel restricting portion is set to 20 nm or more. Due to such a constitution, while preventing the edge light, it is possible to make the distribution of the light emission brightness of the light radiated from the light emitting region (light quantity profile) uniform. Further, the distribution of the current which flows in the organic electroluminescence element becomes uniform and hence, the organic electroluminescence element can obtain the uniform light emission over a long period. Further, portions which wastefully emit bright light for obtaining the desired light emission brightness become no more necessary and hence, a lifetime of the organic electroluminescence element can be prolonged.

Further, in the organic electroluminescence element of the present invention, the thickness of the end portion of the pixel restricting portion at least on the side which restricts the light emitting region is set to a value which is twice or less larger than the thickness of the light emitting layer, and the thickness of the pixel restricting portion is set to 50 nm or more. Due to such a constitution, while preventing the edge light, it is possible to make the distribution of the light emission brightness of the light radiated from the light emitting region (light quantity profile) uniform. Further, the distribution of the current which flows in the organic electroluminescence element becomes uniform and hence, the organic electroluminescence element can obtain the uniform light emission over a long period. Further, portions which wastefully emit bright light for obtaining the desired light emission brightness become no more necessary and hence, a lifetime of the organic electroluminescence element can be prolonged.

Further, in the organic electroluminescence element of the present invention, the thickness of the end portion of the pixel restricting portion at least on the side which restricts the light emitting region is set to a value which is twice or less larger than the thickness of the light emitting layer, and the pixel restricting portion is formed by a sputtering method. Due to such a constitution, the pixel restricting portion can be formed using a dense film and hence, it is possible to easily form the pixel restricting portion which makes a thickness of an end portion thereof on a side which restricts the light emitting region small and, at the same time, prevents the leaking of a current.

Further, according to the present invention, an exposure device may be configured such that the above-mentioned organic electroluminescence elements are arranged in a row and turning on/off of the individual organic electroluminescence elements are controllable independently from each other. The organic electroluminescence element of the present invention eliminates the edge light in the regions other than the light emitting region, and the thickness of the light emitting layer is made uniform and hence, the light emission brightness in the light emitting layer is substantially uniform. Accordingly, the exposure device which adopts such light emitting layer can form an electrostatic latent image having a desired size and a desired potential distribution. Further, the distribution of an electric current which flows in the organic electroluminescence element becomes uniform and hence, the deterioration of the light emitting region of the organic electroluminescence element becomes uniform whereby the product life of the exposure device can be prolonged and, at the same time, it is possible to provide the exposure device which can form a stable latent image over a long period. Still further, in the organic electroluminescence element of the present invention, the light emitting region radiates light uniformly and hence, portions which are made to emit light wastefully to obtain the desired light emission brightness become no more necessary and hence, it is possible to realize the exposure device which exhibits the small power consumption.

Further, present invention also provides an image forming apparatus which includes the above-mentioned exposure device, a photoconductor on which an electrostatic latent image is formed by the exposure device, and a developing means which visualizes the electrostatic latent image which is formed on the photoconductor. By adopting the exposure device of the present invention to the image forming apparatus, a latent image is stably formed for a long period and hence, it is possible to realize the image forming apparatus having the prolonged lifetime. Further, since the exposure device can be obtained using the simple technique, it is possible to provide the image forming apparatus at a low cost. Further, in the image forming apparatus which uses the exposure device of the present invention, a desired electrostatic latent image can be obtained and hence, it is always possible to form the image of high quality. Further, by adopting the organic electroluminescence element as the light source, it is possible to reduce the size of the exposure device and hence, it is possible to realize the compact image forming apparatus by mounting the exposure device on the image forming apparatus.

### Embodiment 1

Hereinafter, an embodiment 1 of the present invention is explained in conjunction with drawings.

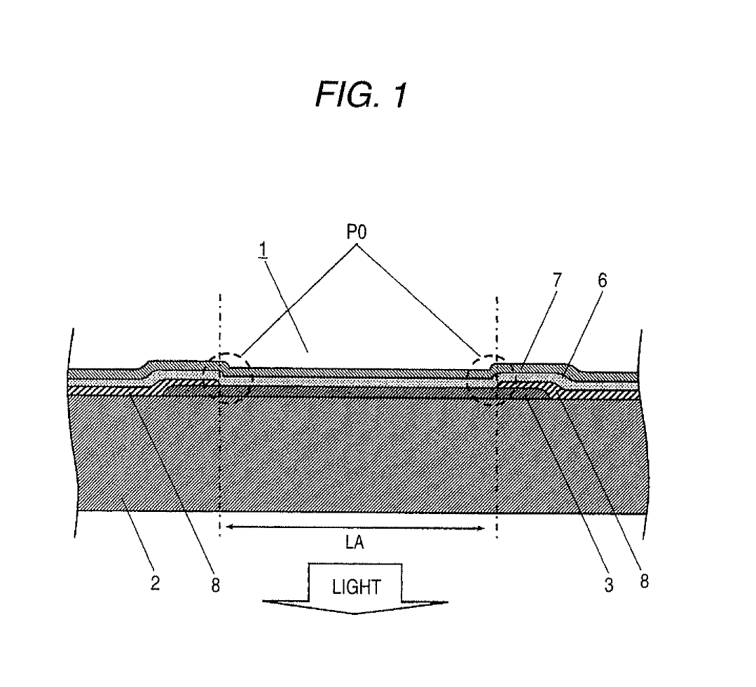

FIG. 1 is an explanatory view which shows the structure of an organic electroluminescence element 1 according to the embodiment 1 of the present invention. Hereinafter, the structure of the organic electroluminescence element 1 according to the embodiment 1 is explained in detail in conjunction with FIG. 1.

In FIG. 1, numeral 1 indicates an organic electroluminescence element according to the present invention. For the sake of brevity, for example, a drive circuit which drives an anode is omitted from FIG. 1. The circuit constitutions or the like for driving the organic electroluminescence element 1 are explained in detail later.

Numeral 2 indicates a colorless and transparent glass substrate. As the glass substrate 2, for example, it is possible to use inorganic oxide glass such as transparent or semitransparent soda ash glass, barium strontium-containing glass, a lead glass, aluminosilicate glass, borosilicate glass, barium borosilicate glass, or quartz glass, or inorganic glass such as inorganic fluoride glass.

It is possible to adopt other material as the material of the glass substrate 2. For example, the glass substrate 2 may be formed of a polymer film made of transparent or semitransparent polyethylene terephthalate, polycarbonate, polymethyl methacrylate, polyethersulfone, polyvinyl fluoride, polypropylene, polyethylene, polyacrylate or amorphous polyolefine, fluorine resin polysiloxane, polysilane, transparent or semitransparent chalcogenide glass such as As₂S₃, As₄₀S₁₀, S₄₀Ge₁₀, a metal oxide or nitride material such as ZnO, Nb₂O, Ta₂O₅, SiO, Si₃N₄, HfO₂, TiO₂. Further, when light which is radiated from a light emitting region is taken out without passing through the substrate, the glass substrate may be formed of a material which is suitably selected from semiconductor materials such as opaque silicon, germanium, silicon carbide, gallium arsenic, nitride gallium or the like, or the above-mentioned transparent substrate materials which include a pigment or the like, and a metallic material or the like which has a surface thereof applied with insulation treatment. Still further, the glass substrate 2 may be formed of a stacked substrate which is formed by stacking a plurality of substrate materials.

Further, on the surface of or in the inside of the glass substrate 2, as described later, a circuit for driving the organic electroluminescence element 1 which is constituted of resistances, capacitors, inductors, diodes, transistors and the like may be formed.

Further, depending on a usage, the glass substrate 2 may be made of a material which allows only a specific wave length to pass therethrough, a material having a light-light converting mechanism which changes one light into another light having a specific wave length may be used. Further, although the substrate may preferably be formed of an insulating material, the material of the substrate is not particularly limited to the insulating material and the substrate may be formed of a conductive material so long as the conductive material does not impede the driving of the organic electroluminescence element 1 or depending on a usage.

Numeral 3 indicates an anode which is made of ITO (indium tin oxide), for example. The anode 3 may be also made of IZO (zinc-doped oxide indium), ATO (Sb-doped SnO), AZO (Al-doped ZuO), ZnO, SnO₂, In₂O₃, or the like in place of ITO. Although the anode 3 may be formed by a vapor deposition method, the anode 3 is preferably formed by a sputtering method. Here, in the embodiment 1, the anode is made of ITO and has a thickness of 150 nm.

Numeral 6 indicates a light emitting layer. In the embodiment 1, the light emitting layer 6 is formed by adopting a so-called coating process which is constituted of simple steps and hence, can realize the reduction of cost. To be more specific, the light emitting layer 6 is formed through steps in which a solution which is produced by dissolving a high-polymer-based or low-polymer-based organic light emitting material which is explained in detail hereinafter into a solvent such as toluene, xylene is coated by a spin coating method.

As the high-molecular organic light emitting material which constitutes the light emitting layer 6, a material having fluorescent or phosphorescent characteristics in a visible region and has good film-formability, for example, a polymer light emitting material such as polypara-phenylene vinylene (PPV), polyfluorene may be used.

Further, the light emitting layer 6 may be formed of a solution which is produced by dissolving a low-molecular organic light emitting material in the above-mentioned solvent may be used. As such an organic light emitting material, besides A1q₃ and Be-benzo quinolinol (BeBq₂), a fluorescent whitening material such as a benzoxazole-based fluorescent whitening material including 2,5-bis(5,7-di-t-pentyl-2-benzo oxazolyl)-1,3,4-thiadiazole, 4,4′-bis(5,7-benzyl-2-benzoxazolyl)stilbene, 4,4′-bis[5,7-di-(2-methyl-2-butyl)-2-benzoxazolyl]stilbene, 2,5-bis(5,7-di-t-benzyl-2-benzoxazolyl)thiophene, 2,5-bis([5-α,α-dimethyl benzyl]-2-benzoxazolyl)thiophene, 2,5-bis[5,7-di-(2-methyl-2-butyl)-2-benzoxazolyl]-3,4-diphenyl thiophene, 2,5-bis (5-methyl-2-benzoxazolyl)thiophene, 4,4′-bis(2-benzoxa iso rill)biphenyl, 5-methyl-2-[2-[4-(5-methyl-2-benzoxa iso rill)phenyl]vinyl]benzoxa iso rill, 2-[2-(4-chloro phenyl)vinyl]naphtha[1,2-d]oxazole, a benzothiazole-based fluorescent whitening material including 2,2′-(p-phenylene di-vinylene)-bis benzothiazole, a benzimidazole-based fluorescent whitening material including 2-[2-[4-(2-benzimiazolyl)phenyl]vinyl]benzimidazole, 2-[2-(4-carboxyphenyl)vinyl]benzoimidazole, a 8-hydroxyquinoline-based metal complex such as tris (8-quinolinol) aluminum, bis(8-quinolinol) magnesium, bis(benzo [f]-8-quinolinol) zinc, bis(2-methyl-8-quinolinolate) aluminum oxide, tris (8-quinolinol) indium, tris (5-methyl-8-quinolinol) aluminum, 8-quinolinol lithium, tris (5-chloro-8-quinolinol) gallium, bis(5-chloro-8-quinolinol) calcium, poly (zinc-bis(8-hydroxy-5-quinolinonyl)methane, a metal chelate-based oxynoid compound such as dilithium epindolidione, a styryl benzene-based compound such as 1,4-bis(2-methyl styryl)benzene, 1,4-(3-methyl styryl)benzene, 1,4-bis(4-methyl styryl)benzene, distyryl benzene, 1,4-bis(2-ethyl styryl)benzene, 1,4-bis (3 ethyl styryl)benzene, 1,4-bis(2-methyl styryl)₂-methyl benzene, a distyl pyrazine derivative such as 2,5-bis(4-methyl styryl)pyrazine, 2,5-bis(4-ethyl styryl)pyrazine, 2,5-bis[2-(1-naphthyl)vinyl]pyrazine, 2,5-bis (4-methoxy styryl)pyrazine, 2,5-bis[2-(4-biphenyl)vinyl]pyrazine, 2,5-bis [2-(1-pyrenyl)vinyl]pyrazine, a naphthalimido derivative, a perilene derivative, an oxadiazole derivative, an aldazine derivative, a cyclopentadiene derivative, a styryl amine derivative, a cumarin-based derivative, an aromatic dimethylidyne derivative or the like may be used. Further, anthracene, salicylate, pyrene, coronene and the like may be used. Alternatively, a phosphorous light emission material such as fac-tris(2-phenyl pyridine) iridium or the like may be also used.

Further, in the embodiment 1, following the conventional example, although the light emitting layer 6 is described as single layer for the sake of convenience, the light emitting layer 6 may adopt a three-layered structure in which a hole transporting layer, an electron block layer and the above-mentioned organic light emitting material layer (all of these layers being omitted from the drawing) are sequentially stacked in order from the anode 3 side. Further the light emitting layer 6 may adopt a two-layered structure in which an electron transporting layer and an organic light emitting material layer (all of these layers being omitted from the drawing) are stacked in order from the anode 3 side, or a two-layered structure in which a hole transporting layer and the organic light emitting material layer (all of these layers being omitted from the drawing) are stacked in order from the anode 3 side, or a seven-layered structure in which a hole injection layer, a hole transporting layer, an electron block layer, an organic light emitting material layer, a hole block layer, an electron transporting layer, an electron injection layer (all of these layers being omitted from the drawing) are stacked in order from the anode 3 side. Still further, the light emitting layer 6 may adopt the more simplified single layer structure which is constituted of only the above-mentioned organic light emitting material. In such a constitution, when the light emitting layer 6 is referred to in the embodiment 1, the light emitting layer 6 may adopt the multilayered structure including functional layers such as a hole transporting layer, an electron block layer, an electron transporting layer. The same goes for other embodiments described later.

With respect to the hole transporting layer in the above-mentioned functional layers, the hole transporting layer may preferably be made of a material having high hole mobility, transparency and high film-forming property. Besides TPD, the hole transporting layer may be made of an organic material such as a porphyrin compound including porphine, tetraphenylporphin copper, phthalocyianine, copper phthalocyianine, titanium phthalocyianine oxide, an aromatic tertiary amine such as 1,1-bis{4-(di-P-tolylamino)phenyl}cyclohexane, 4,4′,4″-trimethyl triphenylamine, N,N,N′,N-tetrakis (P-tolyl)-P-phenylenediamine, 1-(N,N-di-P-tolylamino)naphthalene, 4,4′-bis (dimethylamino)-2-2′-dimethyl triphenylmethane, N,N,N′,N′-tetraphenyl-4,4′-diaminobiphenyl, N,N′-diphenyl-N,N′-di-m-tolyl-4,4′-diaminobiphenyl, N-phenyl carbazole, a stilbene compound including 4-di-P-tolylanimo stilbene, 4-(di-P-tolylamino)-4′-[4-(di-P-tolylamino)styryl]stilbene, a triazole derivative, an oxadizazole derivative, an imidazole derivative, a poly arylalkane derivative, a pyrazoline derivative, a pyrazolone derivative, a phenylenediamine derivative, an annealing amine derivative, an amino substitution chalcone derivative, an oxazole derivative, a styryl anthracene derivative, a fluorenone derivative, a hydrazone derivative, a silazane derivative, a polysilane-based aniline-based copolymer, a polymer oligomer, a styryl amine compound, an aromatic dimethylidyne-based compound, a poly thiophene derivative including poly-3,4 ethylenedioxi thiophene (PEDOT), tetradihexyl fluorenyl biphenyl (TFB), or poly 3-methyl thiophene (PMeT) and the like are used. Further, a hole transporting layer having a polymer dispersion system in which an organic material for a low-molecular hole transporting layer is dispersed in a high polymer such as polycarbonate is used. Further, an inorganic oxide such as MoO₃, V₂O₅, WO₃, TiO₂, SiO, MgO and the like may be used as a material of the hole transporting layer. Still further, these hole transporting materials may be also used as electron blocking materials.

With respect to the electron transporting layer in the above-mentioned functional layers, the electron transporting layer may be made of a polymer material selected from an oxadiazole derivative such as 1,3-bis (4-tert-butylphenyl-1,3,4-oxadiazolyl)phenylene (OXD-7), an anthraquinodimethane derivative, a diphenyl quinine derivative, a silole derivative, or bis(2-methyl-8-dracaena cinnabari linoleate)-(para phenyl phenolete) aluminum (BAIq), vasocupreine or the like can be used. Further, these materials which can form the electron transporting layer may be also used a hole blocking material. Here, in the embodiment 1, a thickness of the light emitting layer 6 is set to approximately 130 nm (including the functional layer).

Numeral 7 indicates a cathode which is made of metal such as Al by a vapor deposition method, for example. The cathode 7 of the organic electroluminescence element may be made of metal or alloy having a low work function, for example, metal such as Ag, Al, In, Mg, Ti, or Mg alloy such as Mg—Ag alloy, Mg—In alloy, or Al alloy such as Al—Li alloy, AL-Sr alloy, Al—Ba alloy. Further, the cathode 7 may be formed of the metal stacked structure which is constituted of a first electrode layer which is made of metal such as Ba, Ca, Mg, Li, Cs or metal fluoride or metal oxide such as LiF, CaO and is brought into contact with the organic material layer and a second electrode which is formed on the first electrode layer and is made of a metal material such as Ag, Al, Ag, In. Here, in the embodiment 1, the cathode 7 is formed of the stacked structure which is made of Ba, Ag and has a thickness of approximately 150 nm.

Numeral 8 indicates a pixel restricting portion which is formed in contact with the anode 3. In the embodiment 1, the pixel restricting portion 8 has at least a thickness of an end portion thereof on a side which restricts the light emitting region, that is, a thickness of the end portion PO of the pixel restricting portion 8 to a value equal to or more than 50 nm and equal to or less than 100 nm.

The pixel restricting portion 8 may preferably be made of a material which exhibits high insulation property, high resistance against dielectric breakdown, high film forming property and high patterning property. However, in the embodiment 1, as a material which constitutes the pixel restricting portion 8, silicon nitride and aluminum nitride are used. These materials are excellent in insulation property, pixel restring accuracy and the like and hence, it is extremely advantageous to adopt these materials. However, these materials are colorless and transparent as the materials which constitute the pixel restricting portion 8 and hence, particularly, a stray light which is confined between the anode 3 and the cathode 7 has an angle thereof converted at a most tip end portion of the end portion PO of the pixel restricting portion 8 whereby an edge light is generated in a region other than the light emitting region LA. However, by setting the thickness of at least the end portion PO of the pixel restricting portion 8 to a value equal to or more than 50 nm and equal to or less than 100 nm, the region where the conversion of angle takes place can be reduced and hence, the edge light is hardly observed in experiments.

Also, it is better to form the pixel restricting portion 8 by patterning the above-mentioned material by the deposition method or by patterning the photoperiodic sensitivity by the photolithography method. (Same apply below-explained embodiments 2 to 4.)

Table 1 shows a result of an experiment in which the pixel restricting portion 8 is made of the above-mentioned material and the thickness of the pixel restricting portion 8 is changed.

TABLE 1

| Thickness of pixel | Ratio of edge light | |
|---|---|---|
| restricting portion [nm] | Lev_b/Lev_a [%] | Evaluation |
| 50 | 0 | Good |
| 100 | 1 | Good |
| 150 | 5 | Fair |
| 200 | 10 | Bad |

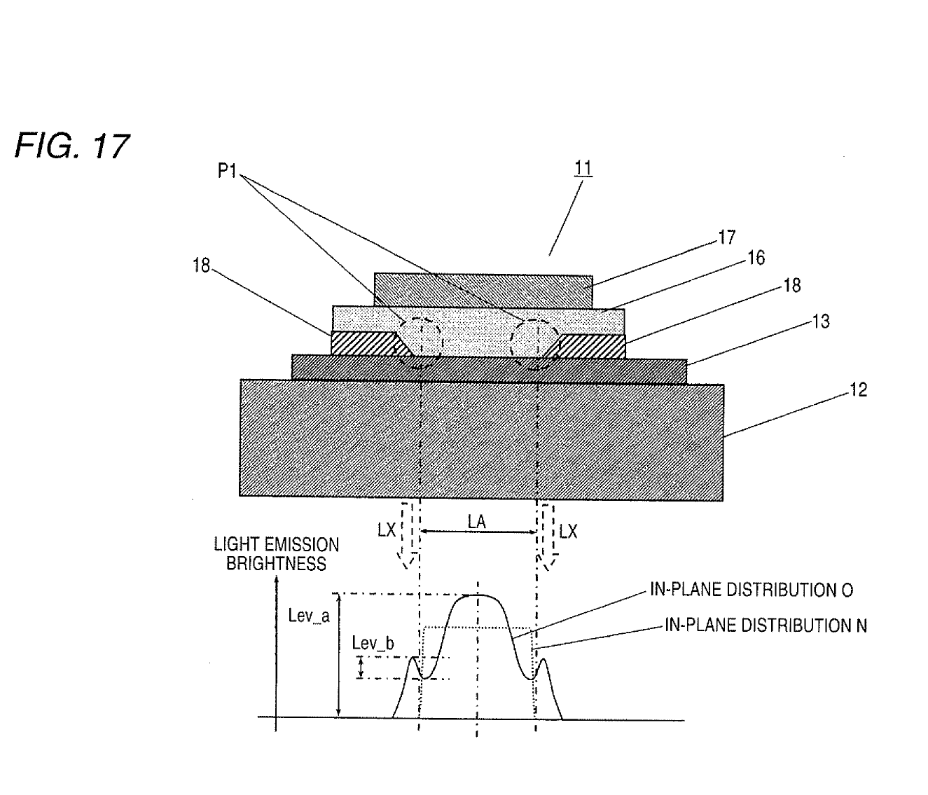

In Table 1, the edge light ratio Leb_b/Leb_a indicates a ratio of the edge light in the in-plane distribution O shown in FIG. 17. As shown in Table 1, along with the decrease of the thickness of the pixel restricting portion 8, the ratio of the edge light is decreased. When the thickness of the pixel restricting portion 8 is set to 100 nm, the ratio of the edge light is reduced to approximately 1%. When it is necessary to reduce the generation of the edge light to a value less than 1%, for example, the vapor deposition time may be controlled so as to set the thickness of the pixel restricting portion 8 to approximately 90 nm.

Even if the edge light is generated by setting the thickness of the pixel restricting portion 8 to a value equal to or more than 50 nm and equal to or less than 100 nm, the exposure device described later can substantially ignore the edge light.

The reason is explained hereinafter. In the embodiment 1, as will be explained in detail later, the organic electroluminescence element 1 is arranged with the resolution of 600 dpi (dot/inch). In this case, the arrangement pitch of the respective elements becomes 42.3 μm. Assuming that the pixel restricting portion 8 occupies approximately 10 μm out of such a pitch, a width of the light emitting region LA becomes substantially approximately 30 μm. Here, assuming the thickness (that is, stepped portion) of the pixel restricting portion 8 as 50 nm and also assuming that the edge light is generated with this width of 50 nm, a ratio of the width of the edge light with respect to a width of the light emitting region LA becomes 300:0.5. Accordingly, an area ratio between a substantial light emitting region which is increased by the edge light and the normal light emitting region LA becomes (300.5²−300²)/300²=0.33%. As described later, in the embodiment 1, the light quantity correction is performed in the exposure device and the accuracy of the light quantity correction is 8 bit, that is, 1/256=0.39% and hence, when the thickness of the pixel restricting portion 8 is set to 50 nm, even under a situation in which the individual organic electroluminescence element 1 radiates or does not radiate the edge light at random, the influence of such a situation can be restricted to 1 step down of the correction accuracy.

When the thickness (that is, stepped portion) of the pixel restricting portion 8 is 100 nm, the ratio of the width of the edge light with respect to the width of the light emitting region LA is 300:1, while an area ratio between the light emitting region increased by the edge light and the normal light emitting region LA becomes (301²−300²)/300²=0.67%. In the case, the correction accuracy corresponds to 7 bits (1/128=0.78%) and hence, when the thickness of the pixel restricting portion 8 is set to 100 nm, even in a state that the individual organic electroluminescent element 1 radiates or does not radiate the edge light at random, the influence can be restricted to a value less than 1 step of the correction accuracy of 7 bits.

Further, the edge light or the uniformity of light emission brightness distribution (light emission profile) in the embodiment 1 may be controlled not only by setting the thickness of the end portion of the pixel restricting portion 8 to a value equal to or more than 50 nm and equal to or less than 100 nm but also by setting the relationship between the thickness of the end portion of the pixel restricting portion 8 and the film thickness of the light emitting layer 6. The uniformity of the light emitting layer 6 is determined based on the film thickness of the light emitting layer 6 and the thickness of the end portion of the pixel restricting portion 8. That is, assuming that the thickness of the light emitting layer 6 is large, even when the thickness of the end portion of the pixel restricting portion 8 is large, provided that the similarity relationship between the thickness of the end portion of the pixel restricting portion 8 and the thickness of the light emitting layer 6 is maintained, it is possible to ensure the uniformity of the thickness of the light emitting layer 6.

Accordingly, it is possible to obtain the favorable uniformity of the light emission thus realizing the suppression of the edge light or the uniformity of the light emission brightness distribution.

In Table 1, the thickness of the light emitting layer 6 is 50 nm. By setting the thickness of the end portion of the pixel restricting portion 8 on a side which restricts the light emitting region of the pixel restricting portion 8 to a value which is twice or less larger than the thickness of the light emitting layer 6, it is possible to obtain the uniform light emission. It is needless to say that the similar effect can be obtained by reducing the thickness of the light emitting layer 6.

Here, with respect to silicon nitride or aluminum nitride which is adopted by the embodiment 1, by suitably applying the sufficient cleaning treatment, ultra-violet ray radiation processing, heat treatment, plasma treatment or the like to these materials after forming the pixel restricting portion 8, it is possible to set a contact angle of these materials with a solvent or a solution at the end portion P0 of the pixel restricting portion 8 to a small value (for example, 45 degrees or less). As the material which constitutes the pixel restricting portion 8, silicon oxide or aluminum oxide may be used. Due to such a constitution, the wettability of the surface of the pixel restricting portion 8 can be improved and hence, the surface is hardly influenced by the capillary phenomenon or surface tension whereby the thickness of the light emitting layer 6 in the light emitting region LA becomes uniform thus eventually making the light emission brightness uniform.

Further, the pixel restricting portion 8 may be made of metal which exhibits the favorable patterning property and makes the injection of the holes into the light emitting layer 6 difficult. That is, assuming a work function of the pixel restricting portion 8 as W_{F1} and a work function of the anode as W_{F2}, the pixel restricting portion 8 may be made of a metal material in which the work function W_{F1} satisfies 2.0[eV]<W_{F1}<W_{F2}.

For example, when the anode 3 is made of ITP (work function W_{F2}=5.0 [eV]), the pixel restricting layer 8 may be made of the metal material which has the work function within a numerical value range of more than 2.0 [eV] and less than 5.0 [eV], for example, Cr (4.5 [eV]), Al (4.2 [eV]), Ag (4.2 [eV]), Mg (3.7 [eV]) or the like. In terms of the value of the work function, it is ideal to select metal such as Li (2.9 [eV]), Na (2.8 [eV]), Ba (2.7 [eV]), K (2.3 [eV]), Cs (2.1 [eV]). However, these metals exhibit high reactivity with water or oxygen and hence, in manufacturing steps of the organic electroluminescent element 1, it is necessary to sufficiently control the atmosphere such as dehydration or deoxidation. Further, the pixel restricting portion 8 may be formed of a plurality of layers using these metal materials or other metal materials. However, since the value of the work function on the side which is bright into contact with the light emitting layer 6 is important, it is desirable that the above-mentioned metal material is arranged on the side of the pixel restricting portion 8 at which the metal material is brought into contact with the light emitting layer 6.

The pixel restricting portion 8 is formed, for example, such that these metal materials are formed into a uniform film by a vapor deposition method or a sputtering method and, thereafter, patterning, developing and etching are applied to the film using a photomask thus forming the pixel restricting portion 8. Further, the pixel restricting portion 8 may be formed by sputtering using a mask.

When the metal material is used as the material of the pixel restricting portion 8, since the metal material is opaque, there is no possibility that an edge light attributed to a stray light is generated different from the previously explained conventional example. However, it is preferable to set the thickness of the pixel restricting portion 8 which is made of the metal to a value equal to or more than 50 nm and equal to or less than 100 nm.

With respect to the thickness of the pixel restricting portion 8, irrespective of whether the material of the pixel restricting portion 8 is the above-mentioned silicon nitride, aluminum nitride or the metal selected based on the work function, the formation of the pixel restricting portion 8 with the decreased thickness contributes to the enhancement of the uniformity of light emission brightness in the light emitting region LA.

However, when the thickness of the pixel restricting portion 8 assumes a value below 50 nm, a defect occurs in the film thus increasing the provability that the light is emitted from a portion from which light should not be emitted originally. That is, the pixel restricting portion 8 cannot ensure the insulation function which the pixel restricting portion 8 is requested to perform originally. On the other hand, when the thickness of the pixel restricting portion 8 exceeds 100 nm, the irregularities of the thickness of the light emitting layer 6 in the light emitting region LA exceed 10% of an average value of the thickness of the light emitting layer 6. In the embodiment 1, by setting the thickness of the pixel restricting portion 8 to 100 nm or less, the irregularities of the thickness of the light emitting layer 6 is suppressed to 10% or less of an average value of the thickness of the light emitting layer 6. By reducing the irregularities of the thickness of the light emitting layer 6 in this manner, it is possible to make the light emission brightness in the light emitting region LA substantially uniform.

Here, “make the light emission brightness substantially uniform” implies that a shape of the distribution (in-plane distribution) of the light emission brightness in the light emitting region LA is made to approximate a rectangular shape (see the in-plane distribution N in FIG. 17). It is preferable in ideal that the shape of the distribution of the light emission brightness in the light emitting region LA assumes the complete rectangular shape. However, in an actual operation, it is difficult to form the pixel restricting portion 8 with a thickness of zero and hence, the light emission brightness is lowered at both end portions of the light emitting region LA. Further, it is impossible to set the coating irregularities of the above-mentioned solvent or solution to zero at the time of forming the light emitting layer 6 and hence, the acquisition of the completely uniform light emission over the whole region of the light emitting region LA is difficult whereby the shape of the in-plane distribution N cannot obtain the completely rectangular shape. With respect to a satisfying degree of “make the light emission brightness substantially uniform”, when the distribution of the light emission brightness in the light emitting region LA exhibits an approximately flat portion at a center portion of the light emitting region LA and the flat portion occupies approximately ⅘ of a width of the light emitting region LA, the distribution of the brightness hardly influences the lifetime of the organic electroluminescence element 1 and hence, it is possible to adopt the organic electroluminescence element 1 as a light source of the exposure device described later.

The above-mentioned constitution is explained in more details hereinafter. When an AC voltage or AC current is applied between the anode 3 and the cathode 7 of the organic electroluminescence element 1, holes are injected into the light emitting layer 6 from the anode 3 and, while electrons are injected into the light emitting layer 6 from the cathode 7. As a result, the re-coupling of the holes and the electrons is generated in the light emitting layer 6 and, when excitons which are generated along with the re-coupling are moved to a ground state from an excited state, a light emitting phenomenon is generated and the emitted light is radiated to air through the anode 3, the glass substrate 2 and the like. Here, in the region where the pixel restricting portion 8 is formed (region other than LA in FIG. 1), the injection of electrons to the light emitting layer 6 is not performed and hence, the light is not radiated.

Usually, in the organic electroluminescence element 1, the region from which the light is radiated, that is, so-called the light emitting region LA is restricted as a region which is sandwiched by the anode 3 and the cathode 7. However, in an attempt to restrict the light emitting region LA by only the positional relationship between the anode 3 and the cathode 7, there arise drawbacks such as the difficulty in constituting a complicated shape such as a circular shape or a hexagonal shape as the light emitting region LA or the generation of irregularities with respect to the size of the light emitting region LA due to the poor positioning accuracy of the anode 3 and the cathode 7. Accordingly, the constitution which restricts the light emitting region LA with the use of the image restricting portion 8 as described in the embodiment 1 is used.

However, as explained in conjunction with the conventional example, when the organic electroluminescence element 1 is formed by the process including a coating step as represented by a spin coating method or the like, in forming the pixel restricting portion 8 which restricts the light emitting region LA between the anode 3 and the cathode 7, the stepped portion is formed at the end portion P0 of the pixel restricting portion 8 and hence, due to the influence of a capillary phenomenon or the surface tension, the thickness of the light emitting layer 6 at the end portion P0 of the pixel restricting portion 8 and the thickness of the light emitting layer 6 at the center portion of the light emitting region LA differ from each other. Due to the difference of the current density which is brought about by such a thickness difference, the distribution of the light emission brightness in the light emitting region LA does not become uniform and, in general, the light emission brightness of the end portion P0 of the pixel restricting portion 8 which exhibits the low current density becomes small compared to the light emission brightness of the center portion of the light emitting region LA. To make the light emission brightness in the light emitting region LA uniform, it is necessary to make at least the thickness of the light emitting layer 6 in the light emitting region LA uniform.

Further, the conventional pixel restricting portion 8 is made of a transparent material such as polyimide in general and hence, light which is generated by the light emitting layer 6 passes through the pixel restricting portion 8 and is radiated. This also becomes one of factors which prevent the light emission brightness in the light emitting region LA from becoming uniform.

Further, when the thickness of the light emitting layer 6 is not uniform, a current flows in a thin portion of the light emitting layer 6 in a concentrated manner and hence, the not only the light emission brightness becomes non-uniform at an initial stage of light emission but also the distribution of the light emission brightness in the light emitting region LA is changed within a long period such that a dark portion becomes a relatively bright portion later due to the lowering of brightness of a portion in which a large quantity of current flows.

By making the thickness of the light emitting layer 6 in the light emitting region LA uniform, the distribution of the current which flows in the organic electroluminescence element 1 becomes uniform and hence, it is possible to obtain the uniform light emission over a long period. Further, when the distribution of the light emission brightness is not uniform, in an attempt to obtain the brightness of a predetermined quantity or more at all portions of the light emitting region LA, regions which radiate light with the brightness more than the brightness which is originally necessary are generated and hence, the lifetime of the organic electroluminescence element 1 is shortened. However, with respect to the organic electroluminescence element 1 of the embodiment 1, it is possible to allow the light emitting region LA to emit light uniformly and hence, it is unnecessary to emit light in a wastefully bright manner to obtain the desired light emission brightness whereby it is possible to allow the organic electroluminescence element 1 to emit light stably over a long period.

Here, as mentioned previously by setting the thickness of the end portion P0 of the pixel restricting portion 8 to a value equal to or more than 50 nm and equal to or less than 100 nm, the generation of the edge light can be prevented, the influence of the edge light can be substantially ignored, and the structure such as the stepped portion at the end portion P0 of the pixel restricting portion 8 can be made small whereby it is possible to easily realize the organic electroluminescence element 1 having the uniform thickness of the light emitting layer 6 in the light emitting region LA thus acquiring the uniform distribution of the light emission brightness of light radiated from the light emitting region LA.

Here, in the embodiment 1, the explanation has been made with respect to a case in which, in the organic electroluminescence element 1, the pixel restricting portion 8 is provided to the anode 3 which is formed on the glass substrate 2 to restrict the light emitting region LA. However, it is needless to say that the technical concept of the embodiment 1 is also substantially applicable to the structure in which the light emitting region LA is restricted by providing the pixel restricting portion 8 to the cathode 7 which is formed on the glass substrate 2.

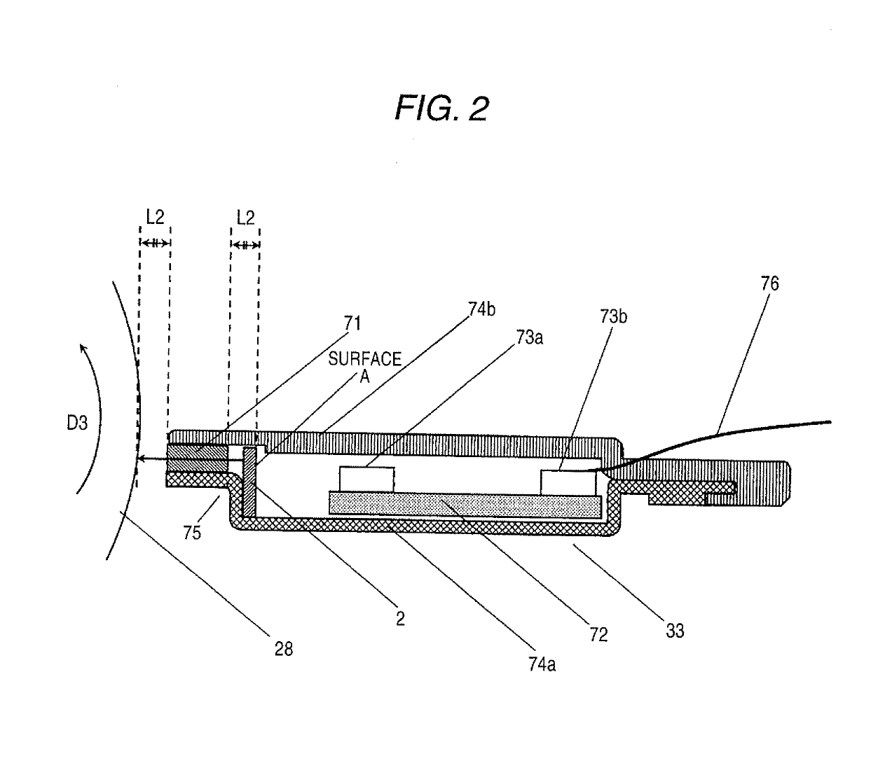

FIG. 2 is a constitutional view of an exposure device according to the embodiment 1 of the present invention. The structure of the exposure device is explained in detail hereinafter in conjunction with FIG. 2.

In FIG. 2, numeral 33 indicates the exposure device which is mounted on an image forming apparatus, wherein the exposure device is a member which forms an electrostatic latent image on a surface of a photoconductor 28. The constitution and the manner of operation of the image forming apparatus are described in detail later.

Numeral 2 indicates the glass substrate which is already explained, and on a surface A of the glass substrate 2, the organic electroluminescence element 1 which constitutes the light emitting element, that is an exposure light source is formed with the resolution of 600 dpi(dot/inch) in the direction perpendicular to the drawing (main scanning direction).

Numeral 71 indicates a lens array in which rod lenses (not shown in the drawing) made of plastic or glass are arranged in a row, wherein the lens array leads a radiated light of the organic electroluminescence element 1 formed on the surface A of the glass substrate 2 on a surface of the photoconductor 28 on which a latent image is formed as a one-to-one magnification erect image. The positional relationship among the glass substrate 2, the lens array 71 and the photoconductor 28 is adjusted such that one focusing point of the lens array 71 rests on the surface A of the glass substrate 2 and another focusing point rests on the surface of the photoconductor 28. That is, assuming a distance from the surface A to a surface of the lens array 71 closer to the surface A as L1 and a distance between another surface of the lens array 71 and the surface of the photoconductor 28 as L2, these distances L1, L2 are set to L1=L2.

Numeral 72 indicates a relay substrate which is formed of a glass epoxy substrate. Numeral 73a indicates a connector A and numeral 73b indicates a connector B, wherein at least connectors A 73a and connectors B 73b are mounted on the relay substrate 72. The relay substrate 72 temporarily relays image data, light quantity correction data and other control signals which are supplied to the exposure device 33 from the outside through a cable 76 such as a flexible flat cable, for example and transmits these signals to the glass substrate 2.

Direct mounting of the connectors on the surface of the glass substrate 2 is difficult in view of the reliability in a joining strength or in a versatile environment in which the exposure device 33 is arranged. Accordingly, this embodiment 1 adopts a FPC (flexible printed circuit) as a joining means which joins the connector A 73a of the relay substrate 72 and the glass substrate 2 (not shown in the drawings and described in detail later), and the joining of the glass substrate 2 and the FPC is performed using an ACF (anisotropic conductive film), for example, wherein the FPC is directly connected to ITO (Indium Tin Oxide) electrodes, for example, which are preliminarily formed on the glass substrate 2.

On the other hand, the connector B 73b is a connector which connects the exposure device 33 and the outside. In general, it is often the case that such connection using the ACF or the like has a problem in a joining strength. However, by providing the connector B 73b which allows a user to connect the exposure device 33 to the relay substrate 72, it is possible to ensure a sufficient strength to the interface to which the user accesses directly.

Numeral 74a indicates a casing A which is formed by bending a metal plate, for example. An L-shaped portion 75 is formed on a side of the casing A 74a which faces the photoconductor 28 in an opposed manner, and the glass substrate 2 and lens array 71 are arranged along the L-shaped portion 75. By adopting the structure in which a photoconductor 28-side end surface of the casing A 74a and an end surface of the lens array 71 are aligned with each other on the same plane and one end portion of the glass substrate 2 is supported on the casing A 74a, forming accuracy of the L-shaped portion 75 can be ensured and hence, the positional relationship between the glass substrate 2 and the lens array 71 can be obtained with high accuracy. In this manner, the casing A 74a is required to have size accuracy and hence, it is desirable to form the casing A using metal. Further, by forming the casing A 74a using metal, it is possible to suppress the influence of noises to the control circuit which is formed on the glass substrate 2 and electronic parts such as IC chips which are mounted on the glass substrate 2 by surface mounting.

Numeral 74b indicates a casing B which is formed by molding using a resin. A cutout portion (not shown in the drawings) is formed in the casing B 74b in the vicinity of the connector B 73b of the casing B 74b, and a user can get access to the connector B 73b through the cutout portion B. Through a cable 76 which is connected to the connector B 73b, the control signals such as the image data, the light quantity correction data, the clock signals and the line synchronizing signals and the like, the drive power source of the control circuit, and the drive power source of the organic electroluminescent elements which constitute the light emitting elements are supplied to the exposure device 33 from the outside of the exposure device 33.

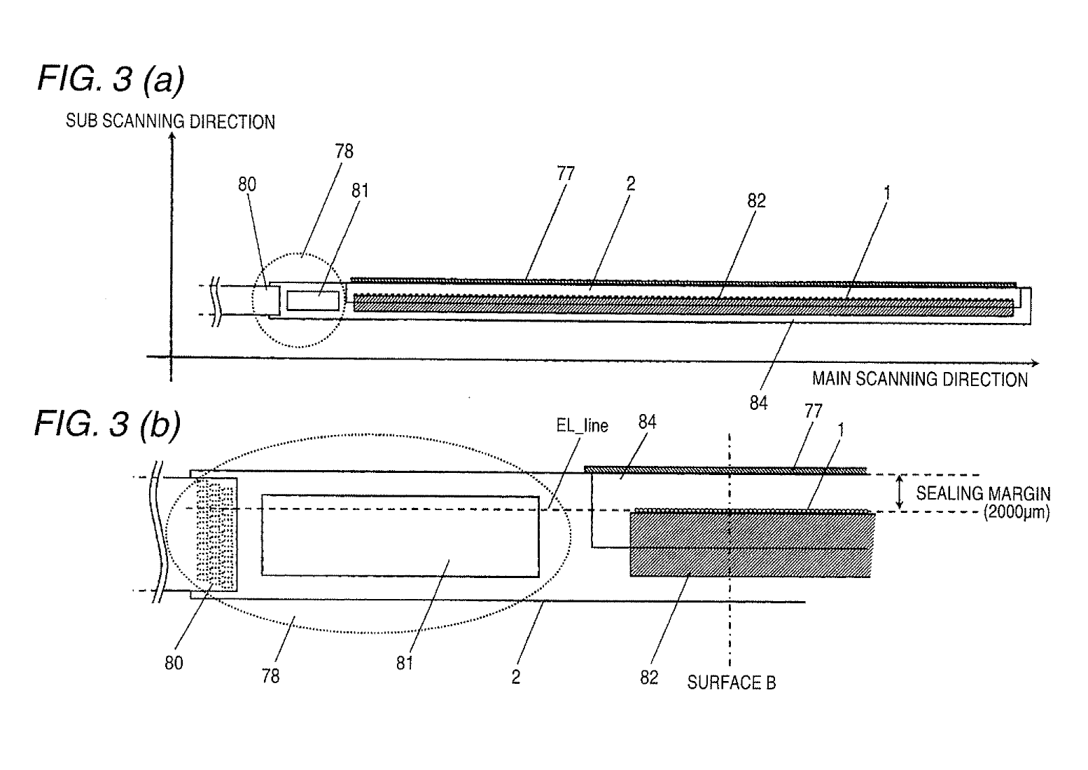

FIG. 3(a) is a top plan view of the glass substrate 2 according to the exposure device 33 of the embodiment 1, and FIG. 3(b) is an enlarged view of an essential part in FIG. 3(a). Hereinafter, the constitution of the glass substrate 2 of the embodiment 1 is explained in detail in conjunction with FIG. 3 together with FIG. 2.

In FIG. 3, the glass substrate 2 is a rectangular substrate having a thickness of approximately 0.7 mm and having at least long size and short size, wherein a plurality of organic electroluminescent elements 1 which constitute light emitting elements is formed in a row along the long-side direction (main scanning direction). In the embodiment 1, the light emitting elements which are necessary for the exposure of at least A4 size (210 mm) are arranged along the long-side direction of the glass substrate 2, and the long-side direction size of the glass substrate 2 is set to 250 mm including an arrangement space for a drive control part 78 described later. Further, although the explanation is made with respect to a case in which the glass substrate 2 has a rectangular shape for the sake of brevity in this embodiment 1, the glass substrate 2 may be modified by cutting a portion thereof for facilitating the positioning of the glass substrate 2 at the time of mounting the glass substrate 2 in the casing A 74a.

Numeral 78 indicates the drive control part which receives control signals (signals for driving the organic electroluminescent elements 1) which constitutes the light emitting elements) which are supplied from the outside of the glass substrate 2 and controls driving of the organic electroluminescent elements 1 based on the control signals. As described later, the drive control part 78 includes an interface means which receives the control signals from the outside of the glass substrate 2 and an IC chip (a source driver) which controls the driving of the light emitting elements based on the control signals received via the interface means.

Numeral 80 indicates an FPC (flexible printed circuit) which constitutes the interface means for connecting the connector A 73a of the relay substrate 72 and the glass substrate 2, wherein the FPC 80 is directly connected to a circuit pattern not shown in the drawing which is mounted on the glass substrate 2 without using connectors or the like. As explained previously, the control is signals such as the image data, the light quantity correction data, the clock signals, the line synchronizing signals and the like which are supplied to the exposure device 33 from the outside, the drive power source of the control circuit, and the drive power source of the organic electroluminescent elements 1 which constitutes the light emitting elements are supplied to the glass substrate 2 through the FPC 80 after temporarily passing through the relay substrate 72 shown in FIG. 2.

In the embodiment 1, 5120 pieces of organic electroluminescent elements 1 as a light source of the exposure device 33 are formed in a row with the resolution of 600 dpi in the main scanning direction, wherein the respective individual organic electroluminescent elements 1 are subjected to a turn ON/OFF control independently by TFT circuits described later.

Numeral 81 indicates the source driver which is supplied as an IC chip which controls the driving of the organic electroluminescent elements 1, and the source driver 81 is mounted on the glass substrate 2 by flip-chip mounting. By taking into consideration that the source driver 81 is mounted on the surface of the glass substrate 2, a bear chip product is adopted as the source driver 81. To the source driver 81, the power source, the control relevant signals such as clock signals, line synchronizing signals and the like, and the light quantity correction data (for example, multiple-value data of 8 bits) are supplied from the outside of the exposure device 33 through the FPC 80. The source driver 81 is, as explained in detail later, a drive parameter setting means with respect to the organic electroluminescent elements 1. To be more specific, the source driver 81 serves to set drive current values of the individual organic electroluminescent elements 1 based on the light quantity correction data received through the FPC 80.

On the glass substrate 2, a joining portion of the FPC 80 and the source driver 81 are connected with each other through a circuit pattern (not shown in the drawing) made of ITO which is formed on the surface of the glass substrate 2 using metal. To the source driver 81 which constitutes the drive parameter setting means, the control signals such as the light quantity correction data, the clock signals, the line synchronizing signals are inputted through the FPC 80. In this manner, the FPC 80 which constitutes the interface means and the source driver 81 which constitutes the drive parameter setting means form the drive control part 78.

Numeral 82 indicates a TFT (Thin Film Transistor) circuit formed on the glass substrate 2. The TFT circuit 82 includes gate controllers such as a shift register and a data latch part which control timing for turning ON and OFF the light emitting elements and a drive circuit which supplies a drive current to individual organic electroluminescent element 1 (hereinafter referred to as a pixel circuit). The pixel circuit is provided to each organic electroluminescent element 1 in one-to-one relationship and is arranged in parallel to the row of light emitting elements which the organic electroluminescent elements 1 form. As described in detail later, by the source driver 81 which constitutes the drive parameter setting means sets a drive current voltage for driving the individual organic electroluminescent element 1 is set to the pixel circuit.

To the TFT circuit 82, the power source, the control signals such as the clock signals, the line synchronizing signals and the like and the image data (binary data of 1 bit) are supplied from the outside of the exposure device 33 through the FPC 80, and the TFT circuits 2 controls the turn on/off timing of individual light emitting element is controlled based on these power source and signals.

Numeral 84 indicates sealing glass. When the organic electroluminescent element 1 is influenced by moisture, the light emitting region is shrunken or minute non-light emitting portion (a dark spot) in the inside of the light emitting region is expanded along with a lapse of time thus remarkably deteriorating the light emitting characteristics. Accordingly, it is necessary to seal the exposure device to interrupt the influence of the moisture to the exposure device. In the embodiment 1, a matted sealing method which adheres the sealing glass 84 to the glass substrate 2 by way of an adhesive agent is adopted. However, to absorb the moisture in the sealing region, a descant not shown in the drawing may be arranged between the sealing glass 84 and the glass substrate 2. The sealing region of several millimeter to several centimeter is necessary in the sub scanning direction from the row of light emitting elements which is constituted by the organic electroluminescent elements 1 in general, wherein 2000 μm is ensured as a sealing margin in the embodiment 1.

Numeral 77 indicates a light quantity sensor unit in which a plurality of light quantity sensors which are made of amorphous silicon or the like is arranged in the main scanning direction along the glass substrate 2. A light emitting quantity of the individual organic electroluminescent element 1 is measured by the light quantity sensor unit 77. An output of the light quantity sensor unit 77 is temporarily fetched to the TFT circuit 82 through a line not shown in the drawing, is amplified by a signal processing means not shown in the drawing, is subjected to signal processing such as analog-digital conversion and, thereafter, is outputted to the outside of the exposure device 33 through the FPC 801 the relay substrate 72 (see FIG. 2) and a cable 76 (see FIG. 2).

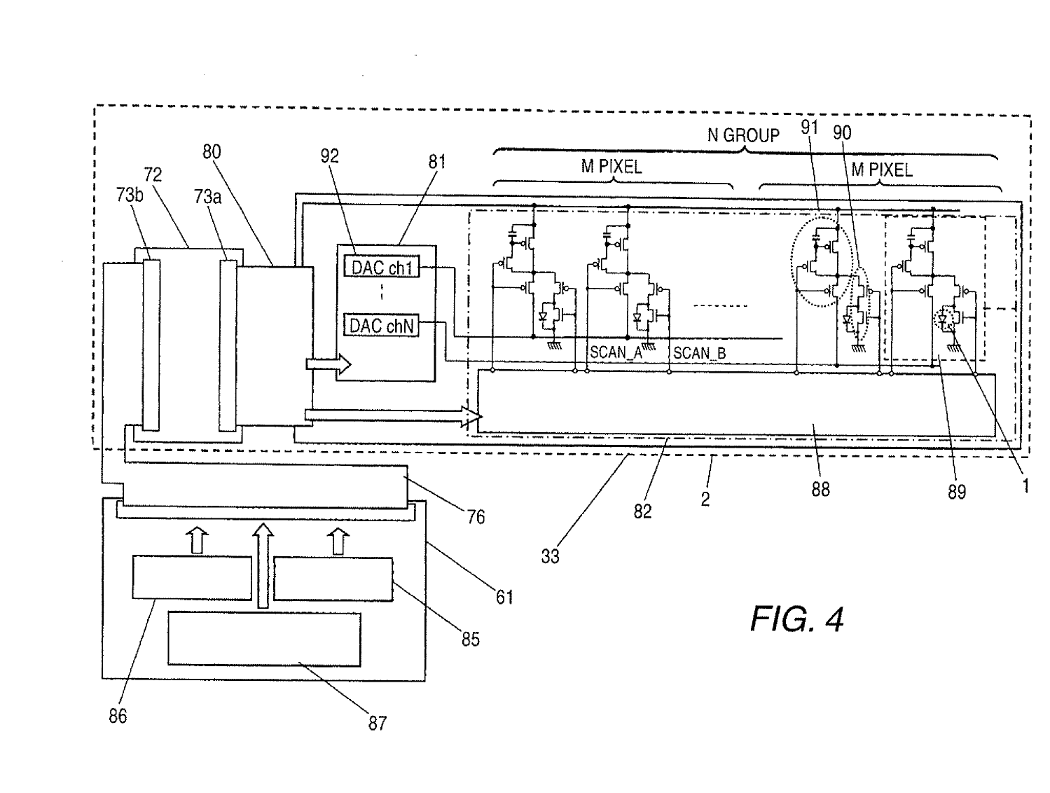

The signal is received and processed by a controller 61 (see FIG. 4) and the light quantity correction data (for example, 8 bits) is generated. However, what is measured by the light quantity sensor unit 77 is the total emitted light quantity of the individual organic electroluminescence elements 1 and is not the distribution of the light emission brightness of the light emitting region. Accordingly, although the total emitted light quantity of the organic electroluminescence elements 1 may be restored by the correction based on the light quantity correction data, it is difficult to restore the distribution of the light emission brightness in the light emitting region.

In the embodiment 1 as mentioned previously, the generation of the edge light in the region other than the light emitting region of the organic electroluminescence element 1 is suppressed (even if the edge light is present, the edge light is within 1 step of accuracy of the light quantity correction) and, further, the light emission brightness within the light emitting region is made uniform and hence, the deterioration of the organic electroluminescence element 1 occurs uniformly whereby even when such deterioration occurs, the distribution of the light emission brightness within the light emitting region is not changed.

Accordingly, the exposure device 33 which uses the organic electroluminescence elements 1 of this embodiment 1 can acquire an extremely remarkable advantageous effect that, as mentioned above, by merely measuring the emitted light quantity of the individual organic electroluminescence elements 1 based on the light quantity sensor unit 77 and by re-setting the drive currents which drive the organic electroluminescence elements 1 based on the measured emitted light quantity, it is possible to surely restore both of the total emitted light quantity of the organic electroluminescence elements 1 and the distribution of the light emission brightness in the light emitting region.

Here, in the embodiment 1, the FPC 80 which is the interface means constituting the drive control part 78 and the source driver 81 which is the drive parameter setting means are positioned on an extension (EL_dir) of the row of light emitting elements which the organic electroluminescence elements 1 form.

Due to such an arrangement, the drive control part 78 is arranged at a position where the drive control part 78 is not overlapped to the row of the light emitting elements at arbitrary positions in the long-side direction (main scanning direction) of the glass substrate 2. Simultaneously, in the above-mentioned constitution, at an arbitrary position along the long-side direction (main scanning direction) of the glass substrate 2, the drive control part 78 is arranged at the position where the drive control part 78 is not overlapped to the TFT circuit (including the pixel circuit) which is formed in parallel to the row of the light emitting elements. Due to such an arrangement, it is possible to reduce a size of the glass substrate 2.

FIG. 4 is a circuit diagram of the exposure device 33 of the embodiment 1 of the present invention. Hereinafter, a lighting control by a TFT circuit 82 and a source driver 81 is explained in detail in conjunction with FIG. 4.

In FIG. 4, numeral 61 indicates a controller which is incorporated into the image forming apparatus. The controller receives an image data from the computer or the like not shown in the drawing and generates the image data which can be printed and, at the same time, generates the light quantity correction data based on an output of the light quantity sensor unit 77 (see FIG. 3) which is incorporated in the exposure device 33 as described above.

Numeral 85 indicates an image memory and the image memory 85 stores binary image data which is generated by the controller 61 based on commands transferred from a computer or the like not shown in the drawing. Numeral 86 indicates a light quantity correction data memory which stores light quantity correction data. The light quantity correction data memory 86 is, for example, a rewritable non-volatile memory such as an EEPROM. Manufacturing steps of the exposure device 33 include a step in which the emitted light quantities and the distributions of light emission brightness of all organic electroluminescence elements 1 are measured with respect to the individual exposure device 33, and the light quantity correction data for making the emitted light quantity of each organic electroluminescence element 1 uniform based on the result of measurement, and the light quantity correction data memory 86 stores the value of the light quantity correction data.

The controller 61 updates this light quantity correction data to newly generated light quantity correction data based on the output of the above-mentioned light quantity sensor unit 77 (see FIG. 3).

Numeral 87 indicates a timing generating part and the timing generating part 87 generates control signals related to timing for driving the exposure device 33. The image data stored in the image memory 85 and the light quantity correction data stored in the light quantity correction data memory 86 (or preliminarily copied in other high-speed memory not shown in the drawing) are supplied from an end portion of the glass substrate 2 through the cable 76, the connector B 73b, the relay substrate 72, the connector A 73a and the FPC 80 in response to signals such as a clock signal, a line synchronizing signal or the like which the timing generating part 87 generates.

Further, the image data and the timing signal which are supplied to the glass substrate 2 are supplied to a TFT circuit 82 through a line which is formed on the glass substrate 2 and constitutes a metal layer formed on an ITO film, for example and, at the same time, the light quantity correction data and the timing signal are also supplied to a source driver 81 in the same manner.

The TFT circuit 82 is roughly divided into a pixel circuit 89 and a gate controller 88. The pixel circuit 89 is provided to individual organic electroluminescence element 1 in one-to-one relationship. The organic electroluminescence elements 1 which amount to M pixels are formed into one group and N groups of organic electroluminescence elements 1 are mounted on the glass substrate 2. In the embodiment 1, one group is constituted of 8 pixels (that is, M=8) and 640 groups are formed. Accordingly, the total number of pixels becomes 5120 pixels (8×640=5120). Each pixel circuit 89 includes a driver part 90 which drives the organic electroluminescence element 1 by supplying an electric current to the organic electroluminescence element 1, and a so-called current program part 91 which allows an incorporated capacitor to store a current value which the driver supplies in performing a turn-on control of the organic electroluminescence element 1 (that is, drive current value of the organic electroluminescence element 1). Here, the pixel circuit 89 can perform constant current driving of the organic electroluminescence element 1 in accordance with the drive current value which is programmed at the predetermined timing.

The gate controller 88 includes a shift register which sequentially shifts inputted binary image data, a latch part which is provided in parallel to the shift register and, upon completion of inputting of predetermined number of pixels to the shift register, collectively holds the image data, and a control part which controls the operational timings of these parts (none of them being shown in the drawing). Further, the gate controller 88 outputs a SCAN_A signal and a SCAN_B signal and controls the timing of a period for performing turning on/off of the organic electroluminescence element 1 connected to the pixel circuit 89 and of a current program period for setting the drive current.

On the other hand, the source driver 81 includes the D/A converters 92 therein, wherein the number (640 pieces in this embodiment 1) of the D/A converters 92 corresponds to the number of groups N of the organic electroluminescence elements 1 (described later). The source driver 81 performs a control to make the emitted light quantities of the respective organic electroluminescence elements 1 equal by setting the drive currents supplied to the individual organic electroluminescence elements 1 based on the light quantity correction data (for example, 8 bits) which are supplied to the source driver 81 through the FPC 80. Here, in the exposure device 33 of this embodiment 1, it is also possible to hold the light emission brightness in the light emitting region of each organic electroluminescence element 1 approximately uniform as mentioned previously.

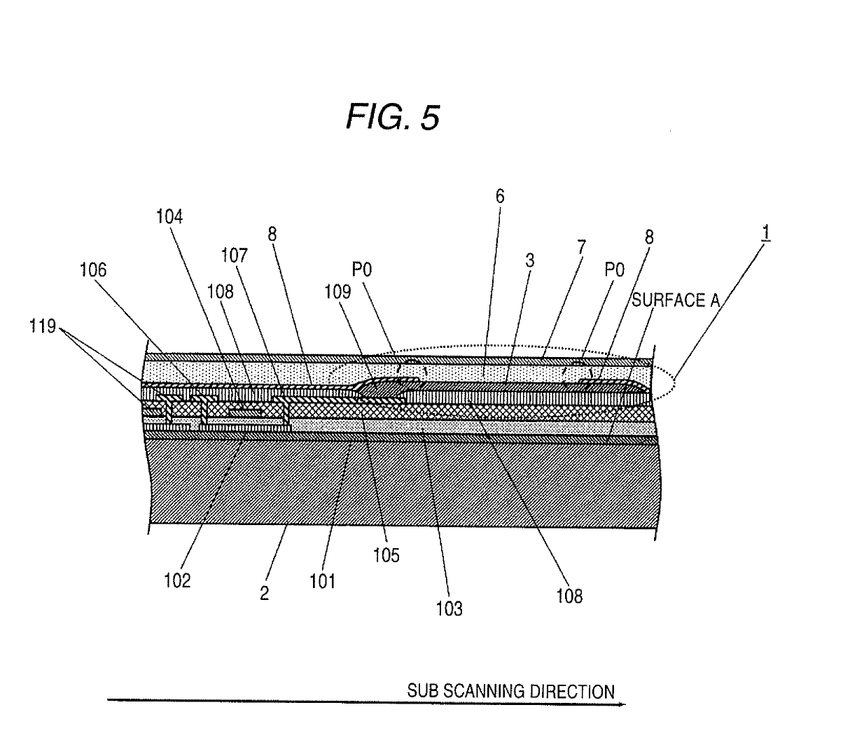

FIG. 5 is a cross-sectional view of the organic electroluminescence elements 1 and the drive circuit according to the exposure device 33 of the embodiment 1 of the present invention. Hereinafter, the constitution of the organic electroluminescence elements 1 in the embodiment 1 is explained in detail in conjunction with FIG. 5.

In FIG. 5, numeral 2 indicates the glass substrate which is already explained in detail.

Numeral 101 indicates a base coating layer which is formed on a surface A on the glass substrate 2 (corresponding to surface A in FIG. 2), and the base coating layer 101 is constituted by stacking an SiN layer and a SiO₂ layer, for example. On the base coating layer 101, a TFT 102 made of polycrystalline silicon (poly-silicon) is formed. In the embodiment 1, although the TFT 102 is made of polycrystalline silicon, the TFT 102 may be made of amorphous silicon. The use of amorphous silicon as a material of the TFT 102 may be disadvantageous in view of a design rule and drive frequency compared with polycrystalline silicon but has an advantage in terms of cost that the manufacturing process is inexpensive.

Numeral 103 indicates a gate insulation layer made of SiO₂, for example, and the gate insulation layer 103 separates and insulates the TFT 102 and a gate electrode 104 which is made of metal such as Mo with a predetermined distance therebetween. Numeral 105 indicates an intermediate layer which is formed by stacking a SiO₂ layer and a SiN layer, for example. The intermediate layer 105 covers the gate electrode 104 and supports a source electrode 106 and a drain electrode 107 which are made of metal such as Al along a surface thereof. The source electrode 106 and the drain electrode 107 are connected to the TFT 102 via contact holes formed in the intermediate layer 105 and the gate insulation layer 103. By applying a predetermined potential to the gate electrode 104 in a state that a predetermined potential difference is applied between the source electrode 106 and the drain electrode 107, the TFT 102 is operated as a switching transistor.

Numeral 108 indicates a protective layer made of SiN or the like and the protective layer 108 completely covers the source electrode 106 and, at the same time, a contact hole 109 is formed in a portion of the drain electrode 107.

Numeral 3 indicates the anode 3 formed on the protective layer 108 and, in this embodiment 1, is made of ITO (Indium Tin Oxide). As a material of the anode 3, besides ITO, IZO (Zinc-doped Oxide Indium), ATO (Sb-doped SnO₂), AZO (Al-doped ZuO), ZnO, SnO₂, In₂O₃, or the like can be used. Although the anode 3 may be formed by a vapor deposition method or the like, the anode 3 is preferably formed by a sputtering method or a CVD method (Chemical Vapor Deposition). The anode 3 is connected to the drain electrode 107 through the contact hole 109.

As explained previously, the pixel restricting portion 8 is formed on the surface of the anode 3. The light emitting layer 6 is formed by a process including a coating step which is represented by a spin coating method or the like, for example, in a state that the light emitting layer 6 is brought into contact with the whole of the anode 3 and the pixel restricting portion 8. Further, the cathode 7 is formed by a vapor deposition method in a state that the cathode 7 is brought into contact with the light emitting layer 6.

The organic electroluminescence element 1 is formed on the glass substrate 2 by the structure and the steps explained heretofore. The TFT 102 is formed in one-to-one relationship with respect to the individual organic electroluminescence element 1 and constitutes electrically a so-called active matrix circuit. The source electrode 106 is used as a positive electrode and a predetermined potential difference is applied between the source electrode 106 and the cathode 7. Further, by controlling the gate electrode 104 to a predetermined potential, the holes are injected to the light emitting layer 6 via the source electrode 106, the TFT 102, the drain electrode 107 and the anode 3, while the electrons are injected into the light emitting layer 6 from the cathode 7. The holes and the electrons are re-coupled to each other in the light emitting layer 6 and a light emitting phenomenon is generated when excitons which are generated along with such re-coupling are moved to a ground state from an excited state.

The light which is radiated from the light emitting layer 6 passes through the anode 3, the intermediate layer 105, the gate insulation layer 103, the base coating layer 101 and the glass substrate 2 and is radiated from a surface opposite to the surface A and exposes a photoconductor not shown in the drawing. In this manner, by adopting the constitution (bottom emission) which takes out light from the substrate surface on the side opposite to the surface A on which the light emitting layer 6 is formed, the sealing of the light emitting layer 6 is facilitated. Numeral 99 indicates a wiring pattern and, for example, analogue signals of the light quantity correction data or the like outputted from the source driver 81 shown in FIG. 4 are connected to the pixel circuit 89 by making use of the wiring pattern 99 formed on the intermediate layer 105.

As has been explained in detail heretofore, the organic electroluminescence element 1 of the embodiment 1 does not generate the edge light in a region other than the light emitting region LA and hence, the light emission brightness in the light emitting region LA becomes uniform whereby the exposure device which uses the organic electroluminescence element 1 as the light source can acquire an electrostatic latent image having a desired shape.

Further, in the organic electroluminescence element 1 of the embodiment 1, the thickness of the light emitting layer 6 is uniform and hence, the distribution of an electric current which flows in the organic electroluminescence element 1 becomes uniform. Accordingly, the deterioration of the light emitting region LA of the organic electroluminescence element 1 becomes uniform and hence, a product lifetime of the exposure device which uses the organic electroluminescence element 1 can be substantially prolonged whereby it is possible to form a stable latent image over a long period. Further, it is unnecessary to make the exposure device to emit light brightly wastefully to obtain the desired light emission brightness thus reducing the power consumption of the exposure device 33.

Here, in the exposure device 33, the structures of the organic electroluminescence elements 1 may be all equal or may be different from each other

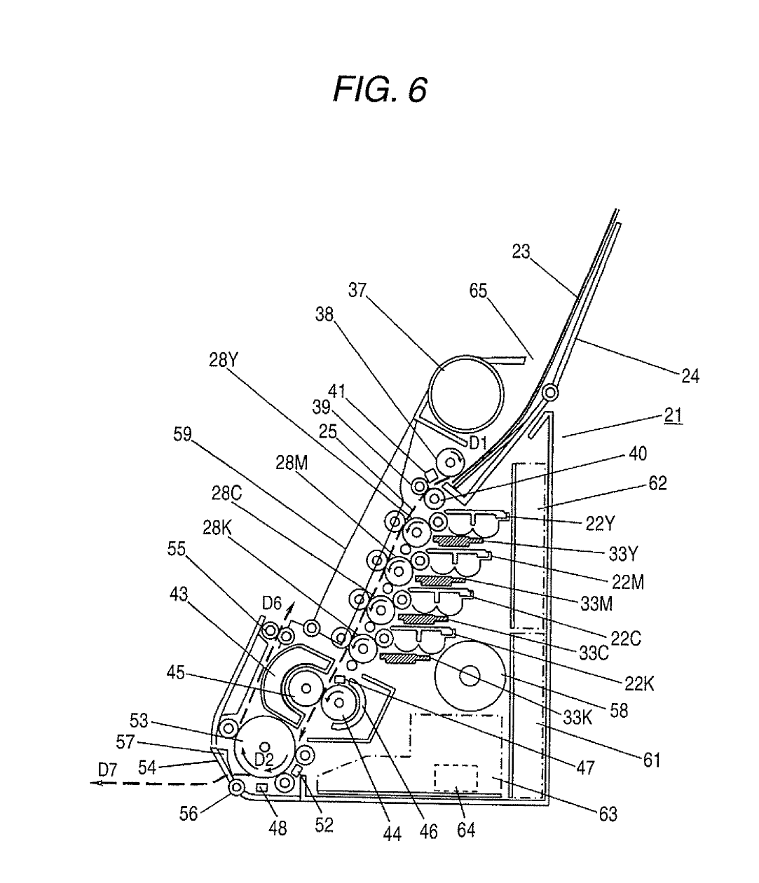

FIG. 6 is a constitutional view of the image forming apparatus on which the exposure device 33 to which the organic electroluminescence element 1 of the embodiment 1 of the present invention is applied is mounted.

In FIG. 6, the image forming apparatus 21 arranges, in the inside of the device, developing stations of four colors consisting of a yellow developing station 22Y a magenta developing station 22M, a cyan developing station 22C and a black developing station 22K in a step-like manner in the vertical direction. A paper feeding tray 24 which incorporates recording papers 23 is arranged above the developing stations 22Y to 22K and, at the same time, at positions corresponding to the respective developing stations 22Y to 22K, recording paper conveying passages 25 which become conveying passages for recording papers 23 which are supplied from the paper feeding tray 24 are arranged in the downward vertical direction.

The developing stations 22Y to 22K form toner images of yellow, magenta, cyan and black in order from an upstream side of the recording paper conveying passage 25, wherein the yellow developing station 22Y includes a photoconductor 28Y, the magenta developing station 22M includes a photoconductor 28M, the cyan developing station 22C includes a photoconductor 28C, and the black developing station 22K includes a photoconductor 28K, wherein each developing station 22Y 22M, 22C or 22K includes a series of members for realizing a developing process in an electrophotographic method such as a developing sleeve, a charger and the like not shown in the drawing.

Further, exposure devices 33Y, 33M, 33C, 33K for forming the electrostatic latent image by exposing surfaces of the photoconductors 28Y to 28K are arranged below the respective developing stations 22Y to 22K.

Here, although the developing stations 22Y to 22K have colors of developers which are filled therein made different from each other, the developing stations 22Y to 22K have the same constitution in spite of the developed colors. To facilitate the explanation made hereinafter, unless otherwise particularly necessary, the explanation is made without specifying the particular color such as the developing station 22, the photoconductor 28 and the exposure device 33.

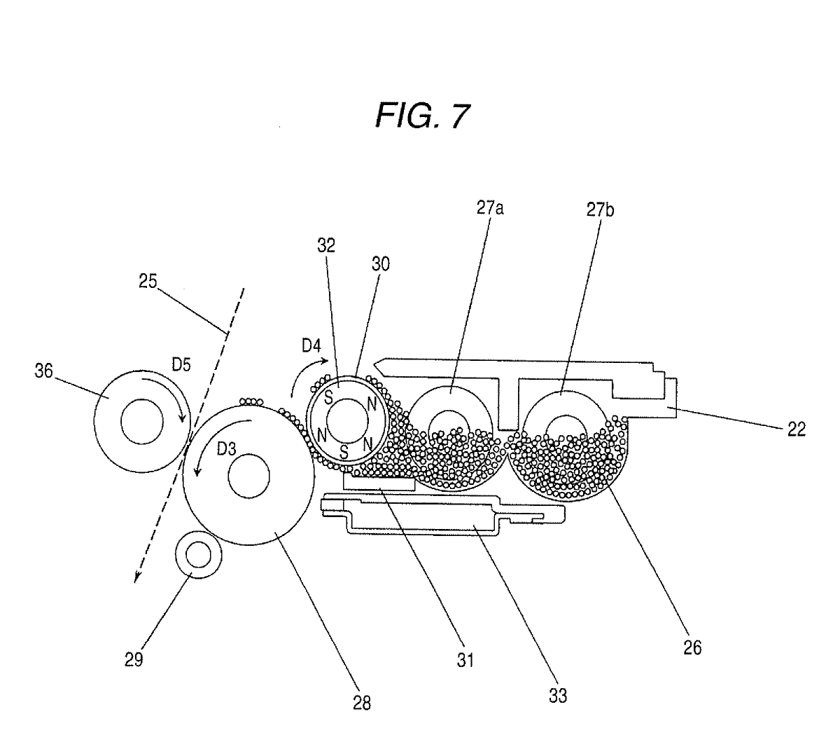

FIG. 7 is a constitutional view showing a periphery of the developing station 22 in the image forming apparatus 21 of the embodiment 1 of the present invention. In FIG. 7, a developer 26 which is a mixture of a carrier and a toner is filled in the inside of the developing station 22. Numerals 27a, 27b are agitation puddles which agitate the developer 26, wherein due to the rotation of the agitation paddles 27a, 27b, the toner in the inside of the developer 26 is charged with a predetermined potential due to a friction with the carrier and, at the same time, the toner is circulated in the inside of the developing station 22 thus providing the sufficient agitation and mixing of the toner and the carrier. The photoconductor 28 is rotated in the direction D3 by a drive source not shown in the drawing. Numeral 29 indicates a charger which charges a surface of the photoconductor 28 with a predetermined potential. Numeral 30 indicates a developing sleeve and numeral 31 indicates a layer thinning blade. The developing sleeve 30 includes a magnet roll 32 on which a plurality of magnetic poles are formed therein. A layer thickness of the developer 26 which is supplied to the surface of the developing sleeve 30 is restricted by the layer thinning blade 31 and, at the same time, the developing sleeve 30 is rotated in the direction D4 by a drive source not shown in the drawing. Due to this rotation and an action of the magnetic poles of the magnet roll 32, the developer 26 is supplied to the surface of the developing sleeve 30 thus developing an electrostatic latent image which is formed on the photoconductor 28 by the exposure device described later and, at the same time, the developer 26 which is not transferred to the photoconductor 28 is recovered in the inside of the developing station 22.

Numeral 33 indicates the exposure device as explained previously. The image forming apparatus 21 to which the exposure device 33 of the embodiment 1 is applied, since the exposure device 33 can stably form the latent image over a long period as mentioned previously, can prolong the product lifetime and, at the same time, since the exposure device 33 of the embodiment 1 can obtain the electrostatic latent image having a desired shape over a long period, can always form an image of high quality.

Further, the exposure device 33 in the embodiment 1 is constituted by arranging the organic electroluminescent elements in a linear array with the resolution of 600 dpi (dot/inch), wherein by selectively turning ON/OFF the organic electroluminescent elements in response to the image data with respect to the photoconductor 28 which is charged with a predetermined potential by the charger 29, an electrostatic latent image of a maximum A4 size is formed. Only the toner out of the developer 26 which is supplied to the surface of the developing sleeve 30 is adhered to the electrostatic latent image portion and hence, the electrostatic latent image is visualized.

At a position which faces the recording paper conveying passage 25 with respect to the photoconductor 28, a transfer roller 36 is provided, and the transfer roller 36 is rotated in the direction D5 by a drive source not shown in the drawing. A predetermined transfer bias is applied to the transfer roller 36 so as to transfer the toner image formed on the photoconductor 28 to the recording paper which is conveyed along the recording paper conveying passage 25.

The explanation is continued by returning to FIG. 6.

As has been explained heretofore, the image forming apparatus 21 of this embodiment 1 is a tandem-type color image forming apparatus which arranges the plurality of developing stations 22Y to 22K in the vertical direction in a step-like manner. The image forming apparatus 21 aims at a size which is equal to a size of a color ink jet printer of the equivalent class. In each developing station 22Y 22M, 22C, 22K, the plurality of units are arranged and hence, to achieve the miniaturization of the image forming apparatus 21, along which the miniaturization of the developing stations 22Y to 22K, it is necessary to reduce sizes of members which contribute to an image forming process and are arranged in a periphery of the developing stations 22Y to 22K so as to make an arrangement pitch of the developing stations 22Y to 22K as small as possible.

To take the easy-to-use property for the user, particularly the accessibility of the user to the recording paper 23 at the time of feeding the paper or discharging the paper when the image forming apparatus 21 is mounted on a desk top in an office or the like into consideration, it is desirable to set a height of image forming apparatus 21 from a bottom surface to a paper feed port 65 to 250 mm or less. To realize such a constitution, it is necessary to suppress a height of the whole developing stations 22Y to 22K to approximately 100 mm in the whole constitution of the image forming apparatus 21.

However, an existing LED head has a thickness of approximately 15 mm, for example and hence, when such an LED head is arranged between the developing stations 22Y to 22K, it is difficult to achieve a targeted constitution. According to a result of the review of inventors and the like of the present invention, by setting a thickness of the exposure device 33 to 7 mm or less, even when the exposure device 33Y, 33M, 33C, 33K is arranged in a gap between the developing stations 22Y to 22K, it is possible to suppress the height of the whole developing station to 10 mm or less.

Numeral 37 indicates toner bottles in which toners of yellow, magenta, cyan and black are stored. Toner conveying pipes not shown in the drawing are arranged between the toner bottles 37 and the respective developing stations 22Y to 22K so as to supply the toners to the respective developing stations 22Y to 22K.

Numeral 38 indicates a paper feed polar. The paper feed roller 38 is rotated in the direction D1 by controlling an electromagnetic clutch not shown in the drawing thus feeding the recording paper 23 loaded in the paper feeding tray 24 to the recording paper conveying passage 25.

To the recording paper conveying passage 25 which is positioned between the paper feed roller 38 and the transfer portion of the yellow developing station 22Y which is arranged at the most upstream side, a pair of a resist roller 39 and a pinch roller 40 is provided as a nip conveying means on an inlet side. The pair of the resist roller 39 and the pinch roller 40 temporarily stops the recording paper 23 which is conveyed from the paper feed roller 38 and conveys the recording paper 23 in the direction toward the yellow developing station 22Y at a predetermined timing. Due to this temporarily stop, a leading end of the recording paper 23 is restricted to be in parallel with the axial direction of the pair of the resist roller 39 and the pinch roller 40 thus preventing skewing of the recording paper 23.

Numeral 41 indicates a recording paper passing detection sensor. The recording paper passing detection sensor 41 is formed of a reflective sensor (photo reflector) and detects the leading end and a trading end of the recording paper 23 based on the presence or the non-presence of a reflection light.

When the rotation of the resist roller 39 is started (the rotation turning ON/OFF operation being performed by controlling the power transmission using an electromagnetic clutch not shown in the drawing), the recording paper 23 is conveyed in the direction toward the yellow developing station 22Y along the recording paper conveying passage 25. Here, using the timing that the rotation of the resist roller 39 is started, the writing timings of electrostatic latent images by the exposure devices 33Y to 33K which are arranged in the vicinity of the respective developing stations 22Y to 22K are independently controlled.

At a portion of the recording paper conveying passage 25 which is positioned further downstream of the most-downstream black developing station 22K, a fixing unit 43 is provided as a nip conveying means on an outlet side. The fixing unit 43 is constituted of a heating roller 44 and a pressing roller 45. The heating roller 44 is a roller having the multi-layered structure which is constituted of a heat generating belt, a rubber roller and a core (none of them shown in the drawing) in order from the surface of the heating roller 44. Here, the heat generating belt is formed of a belt having the three-layered structure which is constituted of a peel-off layer, a silicon rubber layer and a base material layer (none of them shown in the drawing) from a side close to the surface of the belt. The peel-off layer is formed of a fluororesin film having a thickness of approximately 20 to 30 μm thus imparting the peel-off property to the heating roller 40. The silicon rubber layer is formed of a silicon rubber film having a thickness of approximately 170 μm and gives proper resiliency to the pressing roller 45. The base material layer is made of a magnetic material which is alloy of iron, nickel, chromium and the like.

Numeral 26 indicates a back core in which an excitation coil is encased. In the inside of the back core 46, the excitation coil which is formed of a bundle of a predetermined number of copper-made wires (not shown in the drawing) which have surfaces thereof insulated extends in the rotary axis direction of the heating roller 44, and is wrapped around both end portions the heating roller 44 in the circumferential direction of the heating roller 44. By applying an AC current of approximately 30 kHz to the excitation coil from an excitation circuit (not shown in the drawing) which constitutes a semi-resonance type inverter, a magnetic flux is generated in a magnetic path which is constituted of the back core 46 and the base material layer of the heating roller 44. Due to this magnetic flux, an eddy current is generated in the base material layer of the heat generating belt of the heating roller 44 and hence, the base material layer is heated. The heat generated in the base material layer is transmitted to the peel-off layer by way of the silicon rubber layer thus heating the surface of the heating roller 44.

Numeral 47 indicates a temperature sensor for detecting a temperature of the heating roller 44. The temperature sensor 47 is formed of a ceramic semiconductor which is obtained by high-temperature sintering using metal oxide as a main material, wherein the temperature sensor 47 can measure a temperature of an object which is in contact with the temperature sensor 47 by making the use of a change of a load resistance in response to temperature. An output of the temperature sensor 47 is inputted to a control device not shown in the drawing, and the control device controls an electric power which is outputted to the excitation coil in the inside of the back core 46 based on the output of the temperature sensor 47 such that a surface temperature of the heating roller 44 is set to approximately 170° C.

When the recording paper 23 on which the toner image is formed passes a nip portion which is formed by the heating roller 44 to which the temperature control is applied and the pressing roller 45, the toner image formed on the recording paper 23 is heated and pressurized by the heating roller 44 and the pressing roller 45 so that the toner image is fixed to the recording paper 23.

Numeral 48 indicates a recording-paper trading-end detection sensor. The recording-paper trading-end detection sensor 48 monitors a discharge state of the recording paper 23. Numeral 52 indicates a toner image detection sensor. The toner image detection sensor 52 is a reflective sensor unit which uses a plurality of light emitting elements which differ in light emitting spectrum (all visual lights) and a single light receiving element, wherein the toner image detection sensor 52 detects the image density by making use of the difference in absorption spectrum in response to color of image between a background and an image forming portion of the recording paper 23. Further, the toner image detection sensor 52 can detect not only the image density but also the image forming position and hence, in the image forming apparatus 21 of the embodiment 1, the toner image detection sensors 52 are provided at two positions spaced apart in the widthwise direction of the image forming apparatus 21, and the image forming timing is controlled based on detected positions of an image position displacement quantity detection pattern formed on the recording paper 23.

Numeral 53 indicates a recording paper conveying drum. The recording paper conveying drum 53 is a metal-made roller which has a surface thereof covered with rubber having a thickness of approximately 200 μm, and the recording paper 23 after fixing is conveyed in the direction D2 along the recording paper conveying drum 53. Here, the recording paper 23 is cooled by the recording paper conveying drum 53 and, at the same time, is bent in the direction opposite to the image forming surface and is conveyed. Due to such an operation, it is possible to largely reduce curling which may occur when an image of high concentration is formed on a whole surface of the recording paper 23. Thereafter, the recording paper 23 is conveyed in the direction D6 by a kick-out roller 55 and is discharged to a paper discharge tray 59.

Numeral 54 indicates a face-down paper discharging portion. The face-down paper discharging portion 54 is configured to be rotatable about a support member 56, wherein by bringing the face-down paper discharging portion 54 into an open state, the recording paper 23 is discharged in the direction D7. On a back surface of the face-down paper discharging portion 54, a rib 57 is formed along the conveying passage so as to guide the conveyance of the recording paper 23 together with the recording paper conveying drum 53 in a closed state.

Numeral 58 indicates a drive source and a stepping motor is adopted as the driving source 58 in the embodiment 1. The drive source 58 drives the paper feed roller 38, the resist roller 39, the pinch roller 40, peripheral portions of respective developing stations 22Y to 22K including the photoconductors (28Y to 28K) and the transfer rollers (36Y to 36K), the fixing unit 43, the recording paper conveying drum 53 and the kick-out roller 55.

Numeral 61 indicates a controller. The controller 61 receives image data from a computer or the like not shown in the drawing via an external network and develops and form image data which can be printed.

Numeral 62 indicates an engine control part. The engine control part 62 controls hardware and a mechanism of the image forming apparatus 21, wherein the engine control part 62 forms a color image on a recording paper 23 based on the image data transferred form the controller 61 and, at the same time, performs an overall control of the image forming apparatus 21.

Numeral 63 indicates a power source part. The power source part 63 performs the power supply of the predetermined voltage to the exposure devices 33Y to 33K, the drive source 58, the controller 61 and the engine control part 62 and, at the same time, performs the power supply to the heating roller 44 of the fixing unit 43. Further, this power source part 63 also includes a so-called high-voltage power source system such as a charger which charges a surface of the photoconductor 28, a developing bias system which applies a developing bias to the developing sleeves (see numeral 30 in FIG. 7) and a transfer bias system which applies a transfer bias to the transfer rollers 36.

Further, the power source part 63 includes a power source monitoring part 64 so as to monitor a power source voltage which is supplied to at least engine control part 62. A monitor signal is detected by the engine control part 62, wherein the lowering of the power source voltage which is generated when a power source switch is turned off or the service interruption occurs is detected.

In the above-mentioned explanation, the explanation has been made with respect to the case in which the present invention is applied to the color image forming apparatus. However, the present invention is applicable to an image forming apparatus of monochroic color such as black. Further, when the present invention is applied to the color image forming apparatus, the developing colors are not limited to four colors consisting of yellow, magenta, cyan and black.

### Embodiment 2

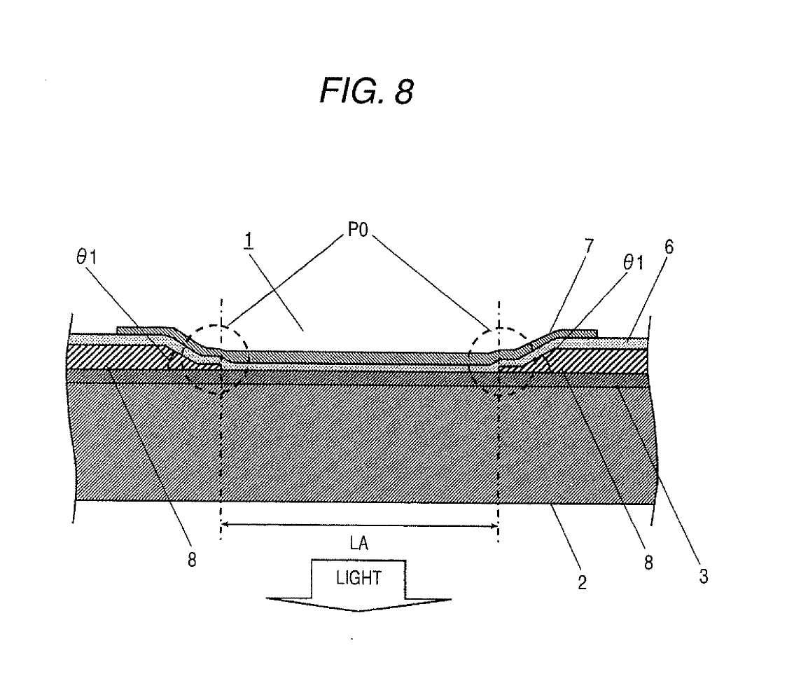

FIG. 8 is a cross-sectional view which shows the structure of the organic electroluminescence element 1 according to the embodiment 2 of the present invention. Hereinafter, although the structure of the organic electroluminescence element 1 according to the embodiment 2 is explained in detail in conjunction with FIG. 8, with respect to an exposure device which adopts the organic electroluminescence element 1 and an image forming apparatus which mounts the exposure device thereon, since there is no difference in the constitution and the operation between the embodiment 1 and the embodiment 2, the explanation thereof is omitted.

In the embodiment 2, the pixel restricting portion 8 has at least a thickness of end portion PO thereof set to a value equal to or more than 50 nm and equal to or less than 100 nm as explained in the embodiment 1 and, at the same time, a thickness of a region of the pixel restricting portion 8 other than the end portion PO of the pixel restricting portion 8 is set larger than a thickness of the end portion P0 of the pixel restricting portion 8 and hence, it is possible to further enhance insulating property which is an original function of the pixel restricting portion 8 while preventing the generation of an edge light and ensuring the uniformity of light emission brightness in the light emitting region LA which the present invention aims at.

In the embodiment 2, at least the end portion PO of the pixel restricting portion 8 is formed of a polymer material which includes a vinyl group, hydrophilic silicon, isocyanate, polyester polymer, polyamide, fluorine-containing polymer, an epoxy group as a backbone chain which exists high wettability to a solvent such as toluene and xylene which dissolves the organic light emitting material explained in detail in the embodiment 1 or the solution in which the organic light emitting material is dissolved, or a polymer material which includes a vinyl group, a glycidyl group, an aryl group or the like on a terminal thereof, or a material which includes a surface having high wettability to the above-mentioned solvent and the solution by applying ultraviolet radiation treatment or plasma treatment to a surface of a repellency material such as polyimide.

Further, in addition to the simple selection of the surface of the material, it is also desirable to make the surface roughness Ra coarse by applying plasma treatment or etching treatment to the end portion P0 of the pixel restricting portion 8 to an extent that the surface roughness Ra of the end portion P0 of the pixel restricting portion 8 becomes approximately 5 nm. In this manner, by selecting the material of the pixel restricting portion 8 and by applying the surface treatment to the pixel restricting portion 8, it is possible to enhance the wettability to the light emitting layer 6 at the end portion P0 of the pixel restricting portion 8. In the embodiment 2, due to the material selection of the pixel restricting portion 8 and the above-mentioned surface treatment, with respect to the degree of the wettability, a contact angle with the solvent or the solution is set to 45 degrees or less. Here, since the surface of the pixel restricting portion 8 is no more smooth surface due to the surface treatment, a light diffusion surface is formed on the surface of the pixel restricting portion 8. As explained previously, the edge light is generated as a result of the phenomenon that the stray light receives the specific conversion of angle due to the pixel restricting portion 8 and hence, assuming the surface of the pixel restricting portion 8 as the light diffusion surface, even when the edge light per se exists, there is no possibility that the edge light is radiated with a specific angle whereby it is possible to substantially control the edge light. In this manner, by intentionally making the surface of the pixel restricting portion 8 coarse, it is possible to impart the high wettability to the solvent such as toluene and xylene which dissolves the organic light emitting material or the solution in which the organic light emitting material is dissolved to the pixel restricting portion 8 thus obtaining both of an advantageous effect that the thickness of the light emitting layer 6 can be made uniform and an advantageous effect that the generation of the edge light is prevented due to the diffusion of light simultaneously.

Further, in the embodiment 2, as shown in FIG. 8, an angle θ1 which is made by the surface of the anode 3 which constitutes the organic electroluminescence element 1 and the pixel restricting portion 8 which is brought into contact with the surface of the anode 3 is set such that the generation of the edge light can be prevented and, at the same time, the light emission brightness in the light emitting region LA becomes substantially uniform. The angle θ1 may preferably be set to a value equal to or more than 3 degrees and equal to or less than 10 degrees as described later.

In forming the end portion P0 of the pixel restricting portion 8 into a tapered shape having a specific angle or into a curved surface having an arbitrary shape in the pixel restricting portion 8, when the end portion P0 of the pixel restricting portion 8 is formed by etching, it is possible to easily adjust the tapered shape and the angle θ1 of the tapered shape by applying an etching method in which a kind of etching gas or an etchant, an etching time and an etching mask are suitably selected. Further, when the end portion P0 of the pixel restricting portion 8 is formed by developing which uses a photosensitive material, it is possible to easily adjust the tapered shape and the angle θ1 by suitably selecting an exposure time, an exposure mask, a developing time and the like.

Particularly, by gradually enlarging an etching region using a plurality of masks and, at the same time, by controlling a thickness of the end portion P0 of the pixel restricting portion 8 which is removed by the etching by adjusting the etching time, it is possible to adjust the angle θ1 which is made by the surface of the anode 3 and the pixel restricting portion 8 brought into contact with the surface of the anode 3 at the end portion P0 of the pixel restricting portion 8 and the shape of the end portion P0 with high accuracy. Accordingly, as shown in FIG. 8, in the end portion P0 of the pixel restricting portion 8, it is possible to provide a flat portion on a most tip end portion which restricts the light emitting region LA.

Here, as described above, although the edge light is generated as the result of the phenomenon that the stray light receives the specific conversion of angle due to the pixel restricting portion 8, since a total amount of the stray light is limited, the intensity of the edge light per unit area is lowered along with the increase of an area which contributes to the conversion of the angle. Narrowing of the angle θ1 contributes to the enlargement of an area of an inclined portion on the end portion P0 of the pixel restricting portion 8 and hence, the narrowing of the angle θ1 is effective in the reduction of the edge light. On the other hand, when the angle θ1 which is made by the surface of the anode 3 and the pixel restricting portion 8 which is brought into contact with the surface of the anode 3 is set to a value less than 3 degrees, in the arrangement pitch of the organic electroluminescence elements 1 which corresponds to 600 dpi of the exposure device, there may be a case that the pixel restricting portion 8 cannot ensure a sufficient film thickness thus decreasing an insulation improving effect.

According to the finding of the inventors of the present invention, as described above, when the contact angle with the above-mentioned solvent or the solution at the end portion P0 of the pixel restricting portion 8 is set to 45 degrees or less, the thickness of the stepped portion of the tip end portion of the end portion P0 of the pixel restricting portion 8 is set to a value equal to or more than 50 nm and equal to or less than 100 nm, and the angle θ1 which is made by the surface of the anode 3 and the pixel restricting portion 8 which is brought into contact with the surface of the anode 3 is changed, by setting the angle θ1 to 45 degrees, the irregularities of the thickness of the light emitting layer 6 in the light emitting region LA becomes approximately 25% and, further, by setting the angle θ1 which is made by the surface of the anode 3 and the pixel restricting portion 8 which is brought into contact with the surface of the anode 3 to 10 degrees, the irregularities of the thickness of the light emitting layer 6 in the light emitting region LA can be suppressed to 10% or less. In this manner, the reduction of the irregularities of the thickness of the light emitting layer 6 directly leads to the enhancement of the uniformity of the light emission brightness in the light emitting region LA, and it is possible to bring the shape of the distribution of the light emission brightness in the light emitting region LA close to the rectangular shape.

Due to the above-mentioned constitution, the generation of the edge light is prevented and, at the same time, the thickness of the light emitting layer 6 is made uniform in the light emitting region LA and hence, it is possible to make the distribution of the light emission brightness of light radiated from the light emitting region LA uniform.

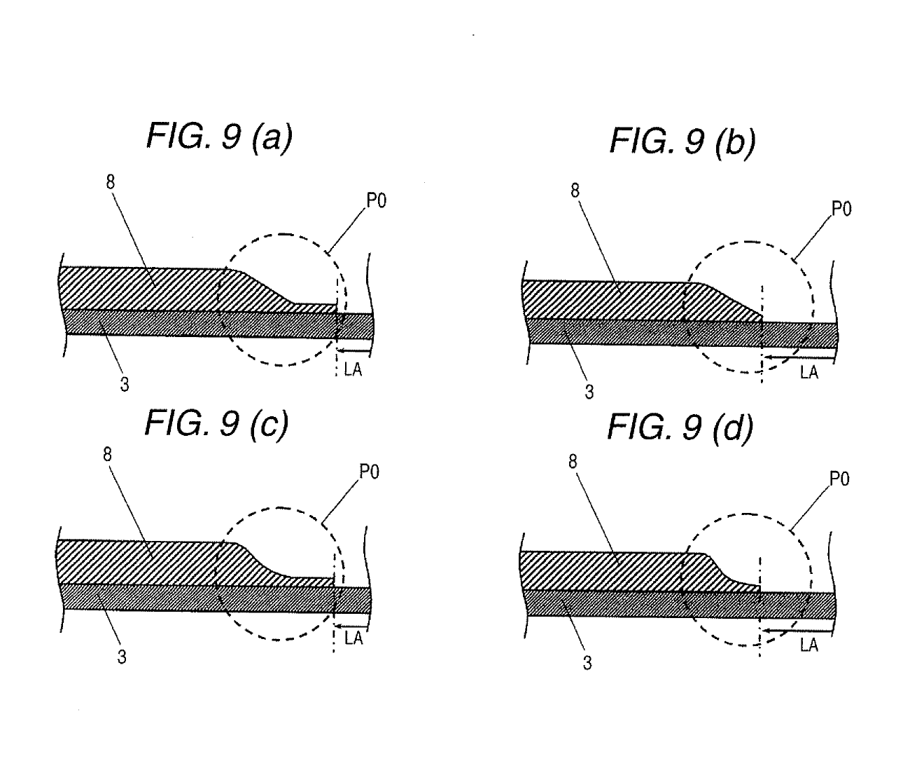

FIG. 9 is a cross-sectional view which illustrates a shape of the end portion P0 of the pixel restricting portion 8 according to the embodiment 2 of the present invention. Hereinafter, the shape of the pixel restricting portion 8 in the end portion P0 of the pixel restricting portion 8 to which the embodiment 2 is applicable is explained in conjunction with FIG. 9.

In FIG. 9(a) to Fig. (c), FIG. 9(a) shows the shape which is explained previously in conjunction with FIG. 8. The most tip end portion of the pixel restricting portion 8 which restricts the light emitting region in the end portion P0 of the pixel restricting portion 8 has a thickness of equal to or more than 50 nm and equal to or less than 100 nm, and the pixel restricting portion 8 includes a flat portion which has a predetermined length from the most tip end portion in the end portion P0 of the pixel restricting portion 8 and, at the same time, the pixel restricting portion 8 includes a tapered shape in a region further away from the most tip end portion thereof.

FIG. 9(b) shows the most tip end portion of the end portion P0 of the pixel restricting portion 8, wherein the most tip end portion has a thickness of 50 nm or more and 100 nm or less and is tapered in the direction away from the most tip end portion. This constitution is advantageous for simplifying the manufacturing process such that, for example, the shape of the pixel restricting portion 8 may be formed by controlling only etching time or the like. In FIG. 9(a) and FIG. 9(b), as described above, the angle which is formed by the tapered shape may preferably be set to a value equal to or more than 3 degrees and equal to or less than 10 degrees from a viewpoint of preventing the generation of the edge light is prevented and of making the light emission brightness in the light emitting region LA uniform.

In FIG. 9(c), in place of forming the pixel restricting portion 8 into a simple tapered shape shown in FIG. 9(a), the pixel restricting portion 8 is formed to exhibit a projecting portion with respect to the anode 3. Since the pixel restricting portion 8 does not have a particular angle component, the pixel restricting portion 8 is advantageous with respect to a point that the generation of the edge light can be suppressed.

In FIG. 9(d), in place of forming the pixel restricting portion 8 into a simple tapered shape shown in FIG. 9(b), the pixel restricting portion 8 is formed to exhibit a projecting portion with respect to the anode 3. Since the pixel restricting portion 8 does not have a particular angle component, the pixel restricting portion 8 is advantageous with respect to a point that the generation of the edge light can be suppressed. Further, in FIG. 9(d), the thickness of the pixel restricting portion 8 is sharply increased from the vicinity of the most tip end portion of the end portion P0 of the pixel restricting portion 8 and hence, the pixel restricting portion 8 is advantageous with respect to a point that it is possible to reduce a size of the organic electroluminescence element 1 including the pixel restricting portion 8 and, at the same time, the whole insulation property can be ensured.

In the examples illustrated in FIG. 9, the shape of the most tip end portion of the end portion P0 of the pixel restricting portion 8 is depicted such that the most tip end portion is formed perpendicular to the anode 3 for the sake of brevity. However, in the actual constitution, the most tip end portion is not formed completely perpendicular to the anode 3 and usually assumes a curved-surface shape. However, by selecting the process conditions in case of forming the pixel restricting portion 8 such that the thickness of the most tip end portion is set to a value equal to or more than 50 nm and equal to or less than 100 nm, it is possible to obtain advantages of the present invention. That is, with respect to a micro shape of the most tip end portion of the end portion P0 of the pixel restricting portion 8, any shape can be adopted. It is needless to say that the formation of the end portion P0 of the pixel restricting portion 8 with an intent to set the thickness of the most tip end portion to the value equal to or more than 50 nm and equal to or less than 100 nm is included in the technical concept of the present invention.

Although the above-mentioned examples are explained on a premise that the pixel restricting portion 8 is made of a transparent material, by forming the pixel restricting portion 8 using a material which prevents at least light having a light emitting wavelength radiated from the light emitting layer 6 from passing through the pixel restricting portion 8, the generation of the edge light can be surely prevented. When the organic electroluminescence element 1 are used as the light source of the exposure device, to match the emitted light of the organic electroluminescence element 1 with the sensitivity of the photoconductor 28 which is already explained in the embodiment 1, the emitted light of the organic electroluminescence element 1 has a wavelength longer than a wavelength λ=660 nm. By forming the pixel restricting portion 8 in which a dye which has an absorption spectrum with respect to this wavelength (a dye which exhibits cyan color to the above-mentioned wavelength) is mixed, it is possible to obviate the above-mentioned lowering of the resistance value and hence, it is possible to further decrease the thickness of the pixel restricting portion 8. Further, as a material which exhibits black, carbon fine particles may be mixed into the pixel restricting portion 8.

Here, in the example 2, the explanation is made with respect t the case in which the light emitting region LA is restricted by forming the pixel restricting portion 8 with respect to the anode 3 which is formed on the glass substrate 2 in the organic electroluminescence element 1. However, it is needless to say that the technical concept of the embodiment 2 is also applicable in the same manner to the structure which restricts the light emitting region LA by forming the pixel restricting portion 8 with respect to the cathode 7 formed on the glass substrate 2.

### Embodiment 3

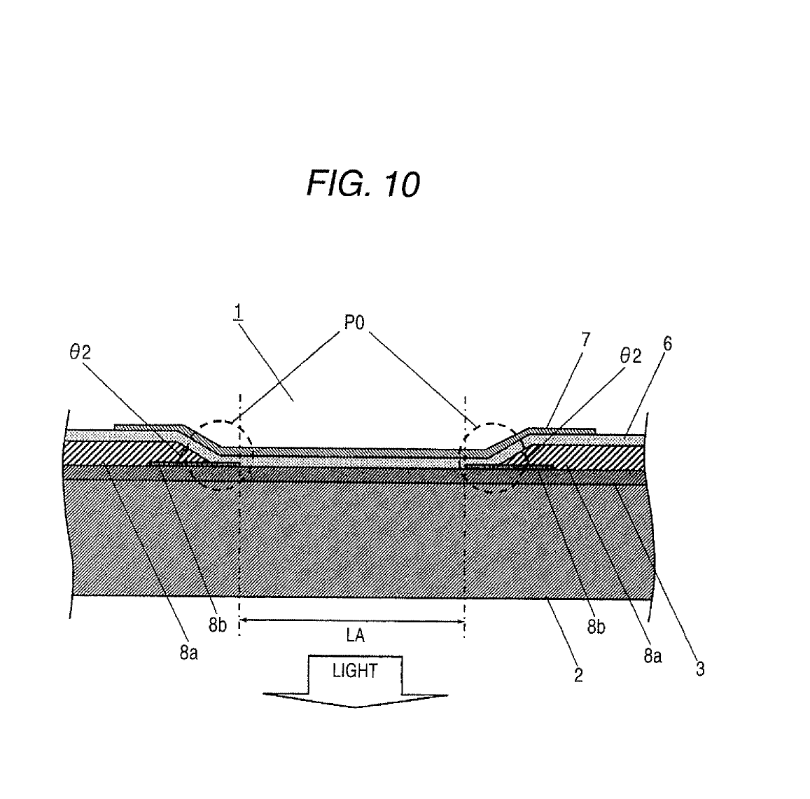

FIG. 10 is a cross-sectional view showing the structure of an organic electroluminescence element 1 in the embodiment 3. Hereinafter, the structure of the organic electroluminescence element 1 in the embodiment 3 is explained in detail in conjunction with FIG. 10. However, with respect to the exposure device to which the organic electroluminescence element 1 is applied and the image forming device on which the exposure device is mounted, the constitution and the action thereof have no difference between the embodiment 1 and the embodiment 3 and their explanations are omitted.

An organic electroluminescence element 1 according to the embodiment 3 includes an anode 3 to which holes are injected, a light emitting layer 6, a cathode 7 to which electrons are injected, and a pixel restricting portion which has a plurality of layers which restricts a light emitting region of the light emitting layer 6 by controlling the injection of at least one of the holes and the electrons, and the thickness of at least an end portion of the pixel restricting portion on a side thereof which restricts the light emitting region is set to a value equal to or more than 50 nm and equal to or less than 100 nm.

The organic electroluminescence element 1 according to the embodiment 3 is further characterized in that the pixel restricting portion is constituted of a first pixel restricting portion 8a which is formed in contact with the anode 3 and a second pixel restricting portion 8b which is formed in contact with the first pixel restricting portion 8a and covers a part of the anode 3, and the thickness of at least the end portion on the side thereof which restricts at least the light emitting region LA of the second pixel restricting portion is set to a value equal to or more than 50 nm and equal to or less than 100 nm.

As shown in detail in FIG. 10, the first pixel restricting portion 8a mainly has a function of ensuring the whole insulating property between the anode 3 and the cathode 7. The second pixel restricting portion 8b mainly has a function of restricting the light emitting region LA. Here, it is preferable that the first pixel restricting portion 8a is made of a which covers with good insulating property between the anode 3 and the cathode 7, and the second pixel restricting portion 8b is made of the materials which can obtain the accuracy such as small thickness and definition. In this manner, by allowing the first pixel restriction portion 8a and the second pixel to use materials different from each other, it is possible to further enhance the function separation effect.

Hereinafter, the structure of the organic electroluminescence element 1 in the embodiment 3 is explained in detail in conjunction with FIG. 10. Here, for the sake of brevity, in the explanation made hereinafter, an end portion of the light emitting region LA which is in contact with the pixel restricting portion 8b in the first pixel restricting portion is referred to as “an end portion P1 of the first pixel restricting portion 8a” (see P0 in FIG. 10).

First of all, the structure of the end portion P0 of the first pixel restricting portion 8a is explained.

On the end portion P0 of the first pixel restricting portion, an angle θ₂ which is made by the surface of the second pixel restricting portion 8b which is formed in contact with the anode 3 and the first pixel restricting portion 8a which is brought into contact with the surface of the second pixel restricting portion 8b is preferably set to a value equal to or more than 3 degrees and equal to or less than 10 degrees. In the embodiment 3, Although the first pixel restricting portion 8a does not directly restrict the light emitting region LA, since the first pixel restricting portion 8a is formed in the vicinity of the second pixel restricting portion 8b, a possibility that the first pixel restricting portion 8a influences the thickness of the light emitting layer 6 in the light emitting region LA when the light emitting layer is formed is zero. Accordingly, it is preferable to apply the condition which is described in the embodiment 2 to the first restricting portion 8a. However, as mentioned above, since the first pixel restricting portion 8a does not directly restrict the light emitting region LA, it is possible to set the moderate condition in comparison to the condition of the embodiment 2. Accordingly, the angle θ2 which is made by the surface of the second pixel restricting portion 8b which is formed in contact with the anode 3 and the first pixel restricting portion 8a which is brought into contact with the surface of the second pixel restricting portion 8b may be set to a value equal to or more than 3 degrees and equal to or less than 45 degrees. However, when both of the first pixel restricting portion 8a and the second pixel restricting portion 8b are made of a transparent material, as explained in conjunction with the second embodiment, from a view point of preventing the generation of the edge light, it is preferable that the angle θ2 which is made by the surface of the second pixel restricting portion 8b which is formed in contact with the anode 3 and the first pixel restricting portion 8a which is brought into contact with the surface of the second pixel restricting portion 8b is set to a value equal to or more than 3 degrees and equal to or less than 10 degrees on the end portion P0 of the first pixel restricting portion 8a.

In the embodiment 3, at least the end portion P0 of the pixel restricting portion 8a is preferably made of a polymer material which includes a vinyl group, hydrophilic silicon, isocyanate, polyester polymer, polyamide, fluorine-containing polymer, an epoxy group as a backbone chain which exhibits a high wettability with a solvent such as toluene and xylene which dissolves the organic light emitting material explained in detail in the embodiment 1 or a solution in which the organic light emitting material is dissolved, or a polymer material which includes a vinyl group, a glycidyl group, an aryl group or the like on a terminal thereof, or a material which includes a surface thereof having a high wettability with the above-mentioned solvent and the solution by applying ultraviolet radiation treatment or plasma treatment to a surface of a repellant material such as polyimide. Further, it is preferable to make the end portion P0 of the first pixel restricting portion 8a coarse so as to set the surface roughness Ra of the end portion P0 to approximately 5 nm by applying plasma treatment or etching treatment to the end portion P0 of the first pixel restricting portion 8a. As mentioned above, by selecting the materials of the first pixel restricting portion 8a and by applying the surface treatment thereto, it is possible to improve the wettability with the light emitting layer 6 on the first pixel restricting portion 8a. In the embodiment 3, by selecting the materials of the pixel restricting portion 8 and by applying the above-mentioned surface treatment thereon, with respect to a degree of the wettability, a contact angle to the above-mentioned solvent or solution on the end portion P0 of the pixel restricting portion 8 is set to 45 degrees or less.

In forming the end portion P0 of the first pixel restricting portion 8a in a tapered shape by etching, it is possible to easily adjust the tapered shape by applying an etching method in which a kind of etching gas or an etchant, an etching time and an etching mask are suitably selected. Further, when the end portion P0 of the first pixel restricting portion 8a is formed by developing by using a photosensitive material, it is possible to easily adjust the tapered shape by suitably selecting an exposure time, an exposure mask, a developing time and the like. Particularly, by gradually enlarging an etching region by using a plurality of masks and, at the same time, by controlling a thickness of the end portion P0 of the first pixel restricting portion 8a which is removed by etching by adjusting an etching time, it is possible to adjust the angle θ2 with high accuracy. Here, also in the embodiment 3, in the same manner as the embodiment 2, the end portion of the first pixel restricting portion 8a may be formed of a curved surface.

Further, as already explained in conjunction with the embodiment 2, it is advantageous to use an opaque material as the material to form the pixel restricting portion. By forming at least one of the first pixel restricting portion 8a and the second pixel restricting portion 8b using a material which prevents light of a wave length emitted by the light emitting layer 6 from passing through the pixel restricting portion 8a or 8b, the angle of the stray light which is confined in the cathode 3 or the glass substrate 2 is not converted and hence, the generation of the edge light can be surely prevented. When the organic electroluminescence element 1 is used as the light source of the exposure device, for example, in order to match the organic electroluminescence element 1 with the sensitivity of the photoreceptor 28 which is already explained in the first embodiment, the emitted light of the organic electroluminescence element 1 is set to have a wavelength longer than a wavelength λ=660 nm. For example, by forming the first pixel restricting portion 8a using a material in which dye (dye which exhibits cyan color with respect to the above-mentioned wavelength) having an absorption spectrum with respect to the wave length is mixed, the generation of the edge light can be prevented. Further, the restricting portion 8a may be formed of a material which mixes carbon particles, for example, therein as a material which exhibits black.

In the embodiment 3, since the first pixel restricting portion 8a and the second pixel restricting portion 8b are functionally separated, by setting the thickness of the first pixel restricting portion 8a to a relatively large value of 5 μm and by forming the first pixel restricting portion 8a using an organic material such as polyimide which controls a quantity of dispersed carbon particles to a relatively low value, it is possible to obtain both of the insulating property and the low light transmissivity which the first pixel restricting portion 8a are required to possess. Here, as described later, when the second pixel restricting portion 8b is formed of a metal material, the stray light is blocked by the second pixel restricting portion 8b and the generation of the edge light is prevented and hence, it is unnecessary to form the first pixel restricting portion 8a with an opaque material.

Next, the second pixel restricting portion 8b is explained in detail.

The second pixel restricting portion 8b mainly has a function of restricting the light emitting region LA and as already explained in other embodiments, it is necessary to obtain wettability of the second pixel restricting portion 8b with respect to the light emitting layer 6. In order to satisfy the requirement, it is preferable that the second pixel restricting portion 8b is formed, for example, using a SiN or an A1N. These materials are excellent in the insulating ability, the pixel restricting accuracy, and moreover, the materials per se are excellent in wettability to the above-mentioned solvent or solution, whereby it is greatly advantageous to adopt these materials. With respect to the sure acquisition of the wettability, by performing the sufficient cleaning treatment, ultraviolet ray irradiation treatment, heat treatment or plasma treatment after forming the pixel restricting portion, it is possible to set the contact angle with the above-mentioned solvent or solution to 45 degrees or less whereby it is possible to ensure the sufficient wettability with respect to the light emitting layer. However, when the second pixel restricting portion 8b is made of the above-mentioned nitride such as SiN, AlN, since these materials are transparent materials, there exists a possibility that the edge light attributed to the first pixel restricting portion 8a is generated. Here, when the opaque material is not used as the material of the first pixel restricting portion 8a, the shape treatment or the surface treatment explained in conjunction with the embodiment 2 may be applied to the first pixel restricting portion 8a.

Due to the same reason as explained before in the embodiment 1, it is preferable that a height of a stepped portion between the anode 3 and the second pixel restricting portion 8b is set to a value equal to or more than 50 nm and equal to or less than 100 nm. By satisfying the condition on the stepped portion, it is possible to prevent the generation of the edge light attributed to the stray light. On the other hand, it is preferable to surely ensure the insulating property by setting the thickness of the first pixel restricting portion 8b to approximately 5 μm at maximum, for example. That is, it is preferable that the thickness of the first pixel restricting portion 8a and the thickness of the second pixel restricting portion 8b are set so as to satisfy the relationship “the thickness 8a of the first pixel restricting portion>the thickness 8b of the second pixel restricting portion”.

Further, the second pixel restricting portion 8b may be made of metal. When the second pixel restricting portion 8b is made of metal, since the light transmissivity can be substantially restricted to zero as explained previously in the embodiment 1, it is possible to surely prevent the generation of the edge light. Here, in the embodiment 3, since the first pixel restricting portion 8a is made of the insulating material to possess the insulating property between the anode 3 and the cathode 7, it is not necessary for the second pixel restricting portion 8b to satisfy the condition of “metal which makes the injection of holes into light emitting layer difficult” required in the embodiment 1. Accordingly, in the embodiment 4, it is possible to use any metal so long as the metal satisfies the patterning property. Also in this case, the generation of the edge light is surely prevented.

However, in FIG. 10, the second pixel restricting portion 8b is independently provided to each organic electroluminescence element 1. However, when the second pixel restricting portion 8b is formed such that the second pixel restricting portion 8b strides over a plurality of the organic electroluminescence elements 1 (that is, in a state that second pixel restricting portion 8b is temporarily formed in a matted state, and openings are formed in predetermined portions of the anode 3), it is not possible to adopt a metal material which exhibits low resistance due to a leakage of a drive current to the neighboring pixel. In this case, it is preferable that the second pixel restricting portion 8b is made of a conductive material which has a predetermined resistance value such as metal oxide or metal nitride, for example. To be more specific, it is possible to use MoO₃ as the metal oxide and SiN as the metal nitride. Further, in this case, it is possible to prevent the leaked current by setting the conductivity in the in-plane direction to 1 MΩ or more. To further enhance the leaked-current suppressing effect, it is further preferable that the conductivity in the in-plane direction is set to 10 MΩ or more.

Here, as the process to obtain the structure shown in FIG. 10, it is possible to form the second pixel restricting portion 8b using a process including the steps of (i) vapor-depositing a material such as SiN, Cr or the like, for example, which forms the second restricting layer 8b in a succeeding step on both of the light emitting region LA and the second pixel restricting portion 8b in the drawing wholly or selectively using a mask, (ii) next, applying a photosensitive resin which forms the second pixel restricting portion 8a to the whole surface, (iii) forming the first pixel restricting portion 8a by exposing and developing by using a photomask which has a shape of the first pixel restricting portion 8a and, thereafter, (iv) applying etching treatment by using the first pixel restricting portion 8a in place of a photomask.

In this case, in the etching treatment, since the second pixel restricting portion 8b is removed from a center portion of the light emitting region LA, by reducing the time for the etching, it is possible to form the second pixel restriction portion 8b in a shape projecting from the end portion P1 of the first pixel restriction portion 8a to the light emitting region LA.

In this manner, by patterning the second pixel restricting portion 8b made of other material via the pattered photosensitive resin, it is possible to easily realize the first pixel restricting portion 8a and the second pixel restricting portion 8b which are made of a plurality of materials without using complicated steps such as positioning or the like. Here, the photosensitive resin is suitably used as the material of the first pixel restricting portion 8a since the resin has generally high insulating property. Further, by adjusting the condition for patterning of the photosensitive resin or patterning of other material, it is also possible to realize to form a complicated shape in which a size of one portion is larger than a size of another portion.

Here, when the first pixel restricting portion 8a is made of a material in which a dye having an absorption spectrum to a wavelength of the emitting light of the organic electroluminescence element is mixed as mentioned above, it is possible to prevent the generation of the edge light. Further, as a material which exhibits black, for example, a material in which fine particles of carbon are mixed may be used.

Due to the above-mentioned constitution, it is possible to prevent the generation of the edge light in the region except the light emitting region LA and, at the same time, it is possible to make the thickness of a light emitting layer 6 in the light emitting region LA uniform. Further, it is also possible to make the distribution of light emission brightness of a light radiated from the light emitting region LA uniform.

Here, in the embodiment 3, the explanation has been made with respect to the case in which the pixel restricting portion 8a and the pixel restricting portion 8b to the anode 3 formed on the glass substrate 2 in the organic electroluminescence element 1. However, it is needless to say that it is needless to say that the technical concept of the embodiment 3 is also applicable to the structure in which the light emitting region LA is restricted by providing the pixel restricting portion 8a and the pixel restricting portion 8b to the cathode 7 formed on the glass substrate 2.

### Embodiment 4

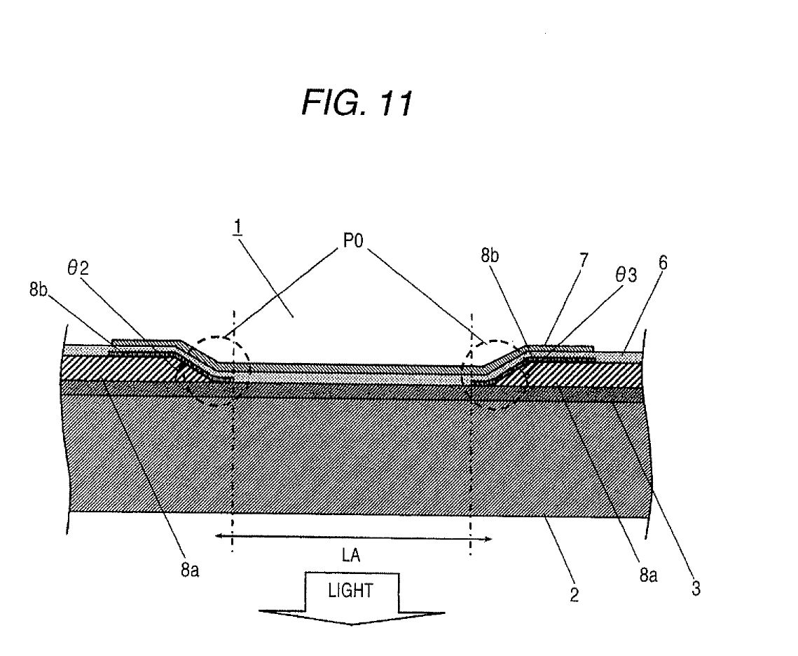

FIG. 11 is a cross-sectional view showing the structure of an organic electroluminescence element 1 in the embodiment 4. Hereinafter, the structure of the organic electroluminescence element 1 in the embodiment 4 is explained in detail in conjunction with FIG. 11. However, with respect to the exposure device to which the organic electroluminescence element 1 is applied and the image forming device on which the exposure device is mounted, the constitution and the action thereof have no difference between the embodiment 1 and the embodiment 4 and hence, their explanations are omitted.

An organic electroluminescence element 1 according to the embodiment 4 includes an anode to which holes are injected, a light emitting layer 6, a cathode to which electrons are injected, and a pixel restricting portion which has a plurality of layers which restricts a light emitting region of the light emitting layer 6 by controlling the injection of at least one of the holes and the electrons, and the thickness of at least an end portion of the pixel restricting portion on a side thereof which restricts the light emitting region is set to a value equal to or more than 50 nm and equal to or less than 100 nm.

The organic electroluminescence element 1 according to the embodiment 4 is further characterized in that the pixel restricting portion is constituted of the second pixel restricting portion 8b which is formed in contact with the anode 3 and the first pixel restricting portion which is formed in contact with the second pixel restricting portion and covers a portion of the second pixel restricting portion, and the thickness of the end portion on the side thereof which restricts at least the light emitting region LA of the second pixel restricting portion 8b is set to a value equal to or more than 50 nm and equal to or less than 100 nm.

As shown in detail in FIG. 11, the first pixel restricting portion 8a has a function which mainly ensures an overall insulating property between the anode 3 and the cathode 7. The second pixel restricting portion 8b has a function which mainly restricts the light emitting region LA. In this case, the first pixel restricting portion 8a may preferably be made of a material which covers with high insulating manner between the anode 3 and the cathode 7, and the second pixel restricting portion 8b may preferably made of a material which possesses the accuracy such as small thickness and definition. In this manner, it is possible to enhance the advantageous effects brought about by the function separation effect by allowing the first pixel restriction portion 8a and the second pixel restriction portion 8 to use materials different from each other.

Hereinafter, the structure of an organic electroluminescence element 1 according to the embodiment 4 is explained in detail in conjunction with FIG. 11.

Firstly, the structure of the end portion P0 of the first pixel restricting portion 8a is described.

In the embodiment 3, by forming the second pixel restricting portion 8b using an opaque material or the like, it is unnecessary to take the transmissivity of the first pixel restricting portion 8a into account. However, the embodiment 4 adopts the structure in which the second pixel restricting portion 8b covers the first pixel restricting portion 8a and hence, it is also necessary to take the countermeasure to prevent the generation of the edge light on the first-pixel-restricting-portion-8a side. For this end, in the same manner as explained in the embodiment 2, at the end portion P0 of the first pixel restricting portion 8a, it is preferable to set an angle θ3 made by the surface of the anode 3 and the first pixel restricting portion 8a which is formed in contact with the anode 3 to a value equal to or more than 3 degrees and equal to or less than 10 degrees.

Further, in the embodiment 4, since the second pixel restricting portion 8b is arranged at a position which is sandwiched between the first pixel restricting portion 8a and the light emitting layer 6 and hence, as described in the embodiment 2, the angle θ3 directly influences the uniformity of thickness of the light emitting layer 6. Here, in the embodiment 4, since the second pixel restricting portion 8b covers the first pixel restricting portion 8a, it is not always necessary to form the first pixel restricting portion 8a using a material which exhibits high wettability to toluene or wylene which dissolves an organic light emitting material or a solution in which an organic light emitting material is dissolved. Further, it is unnecessary to apply the treatment for maintaining the contact angle of the solvent or the solution with respect to the surface within a given range.

To form the end portion P0 of the first pixel restricting portion 8a in a tapered shape, when the end portion P0 of the first pixel restricting portion 8a is formed by etching, it is possible to easily adjust the tapered shape by applying an etching method in which a kind of etching gas or an etchant, an etching time and etching mask are suitably selected. Further, when the end portion P0 of the first pixel restricting portion 8a is formed by developing which uses a photosensitive material, it is possible to easily adjust the tapered shape by suitably selecting an exposure time, an exposure mask, a developing time and the like. Especially, an etching region is gradually enlarged using a plurality of masks and, at the same time, a thickness which is removed by means of the etching is controlled by adjusting the etching time and hence, it is possible to adjust the angle θ3 with high accuracy Here, also in the embodiment 4, same as shown in the embodiment 2, the end portion of the first pixel restricting portion 8a may be constituted by using a curved surface.

Further, as explained in conjunction with the embodiment 2, it is advantageous to use the opaque material as the material to form the pixel restricting portion. In the embodiment 4, by forming the first pixel restricting portion 8a using a material which prevents light having an emitting light wave length which is emitted from the light emitting layer 6 from passing through the first pixel restricting portion 8a, a stray light confined in the anode 3 or in the glass substrate 2 is not subjected to the conversion of angle and hence, the generation of the edge light is surely prevented.

In the embodiment 4, since the first pixel restricting portion 8a and the second pixel restricting portion 8b are functionally separated in the same manner as in the embodiment 3, by setting the thickness of the first pixel restricting portion 8a to a relatively large value of approximately 5 μm at maximum and by constituting the first pixel restricting portion 8a using an organic material such as polyimide which contains a quantity of dispersed carbon particles which is controlled to a relatively low value, it is possible to obtain both of insulating property and a low light transmissivity which the first pixel restricting portion 8a is requested to satisfy.

Next, the second pixel restricting portion 8b is explained in detail.

The second pixel restricting portion 8b mainly has a function of restricting the light emitting region LA. As explained previously in conjunction with other embodiments, the second pixel restricting portion 8b is required to ensure the prevention of the edge light and the maintenance of the wettability with respect to the light emitting layer 6. To satisfy the requirements, it is preferable that the second pixel restricting portion 8b is formed, for example, of SiN or AlN. These materials exhibit the excellent insulating property, the excellent pixel regulating accuracy. Further, the material per se exhibits the excellent wettability to the solvent or the solution and hence, it is largely advantageous to adopt these materials. By applying the sufficient washing treatment, an ultraviolet ray radiation treatment, the heat treatment, the plasma treatment or the like after forming the pixel restricting portion 8, it is possible to set the contact angle at the end portion P2 of the second pixel restricting portion 8b with respect to the solvent or the solution to a value equal to or less than 45 degree and hence, the sufficient wettability with respect to the light emitting layer 6 can be ensured.

Due to the same reason as explained previously in the embodiment 1, it is preferable that a height of a stepped portion between the anode 3 and the second pixel restricting portion 8b is set to a value equal to or more than 50 nm and equal to or less than 100 nm. By satisfying the condition on the stepped portion, it is possible to prevent the generation of an edge light attributed to a stray light. On the other hand, it is preferable to surely ensure the insulating property by setting the thickness of the first pixel restricting portion 8b to approximately maximum 5 μm, for example. That is, it is preferable that the thickness of the first pixel restricting portion 8a and the thickness of the second pixel restricting portion 8b are set so as to satisfy the relationship of “the thickness of the first pixel restricting portion>the thickness of the second pixel restricting portion”.

Here, in the embodiment 4, since the first pixel restricting portion 8a is made of the insulating material to bear the insulating property between the anode 3 and the cathode 7, it is not necessary to satisfy the condition of “metal which makes the injection of holes into light emitting layer difficult” required in the embodiment 1. Accordingly, in the embodiment 5, it is possible to use any metals which satisfy the patterning property.

However, as shown in FIG. 11, although the second pixel restricting portion 8b is independently provided in respective organic electroluminescence element 1, when the second pixel restricting portion 8b strides over a plurality of the organic electroluminescence element 1 and formed (that is, once formed in a matted state such that the opening portion is arranged on the predetermined position of the anode 3), it is not possible to adopt the low-resistance metallic material due to the leakage of the drive current to the neighboring pixel. In this case, it is preferable for the second pixel restricting portion 8b to use, for example, a conductive material which has predetermined resistance value such as a metal oxide or a nitride. To be more specific, it is possible to use MoO3 for the metal oxide, SiN for the nitride or the like. Further, in this case, it is possible to prevent the leakage current when the conductivity in the in-plane direction is 1 MΩ or higher. To further enhance restrictive effect of the leakage current, with respect to the conductivity in the in-plane direction, it is preferable that the conductivity is further 10 MΩ or higher.

By using the materials as explained above, it is possible to prevent the generation of the edge light in the region except the light emitting region LA and, at the same time, to made uniform the thickness of a light emitting layer 6 in the light emitting region LA, and to made uniform a distribution of light emission brightness of a light radiated from the light emitting region LA.

Here, in embodiment 4, although, the embodiment when the light emitting region LA is restricted by providing the pixel restricting portion 8a and the pixel restricting portion 8b to the anode 3 formed on the glass substrate 2 in the organic electroluminescence element 1 is explained, it is needless to say that the technical concept of the embodiment 4 can also be applied to the structure which the light emitting region LA is restricted by providing the pixel restricting portion 8a and the pixel restricting portion 8b to the cathode 7 formed on the glass substrate 2.

As has been explained heretofore in conjunction with the plurality of embodiments, according to the organic electroluminescence element 1 of the present invention, the edge light is not generated in the end portion P0 of the pixel restricting portion 8 and, at the same time, the light emission brightness in the light emitting region LA which is restricted by the pixel restricting portion 8 can be made substantially uniform Accordingly, the exposure device which includes the organic electroluminescence elements 1 of the present invention can obtain the electrostatic latent image having a desired shape.

Further, in the organic electroluminescence element 1 of the present invention, the irregularity of thickness of the light emitting layer 6 in the light emitting region which is restricted by the pixel restricting portion 8 are set to a value equal to or less than 10% of an averaged value of the thickness of the light emitting layer in the light emitting region and hence, the thickness of the light emitting layer 6 is uniform whereby the distribution of the current which flows in the organic electroluminescence element 1 becomes uniform. Accordingly, the deterioration of the light emitting region LA of the organic electroluminescence element 1 becomes uniform and life time of the organic electroluminescence element 1 is substantially prolonged and, at the same time, it is possible to provide the exposure device which can form the stable latent image for a long period. Further, in the organic electroluminescence element 1 of the present invention, the light emitting region LA uniformly emits light and hence, it is unnecessary to allow the organic electroluminescence element 1 to emit light wastefully to obtain the desired light emission brightness and hence, it is possible to realize the exposure device which exhibits the small power consumption.

In the image forming device to which the exposure device of the present invention is applied, the exposure device can stably form the latent image for a long time and hence, the image forming apparatus having a prolonged lifetime can be realized. Further, since the exposure device can be obtained by a simple fabrication method, the image forming apparatus can be provided at a low cost. Still further, in the image forming apparatus which uses the exposure device of the present invention, the desired latent images can be obtained and hence, the image having high image quality can be always formed. Further, by adopting the organic electroluminescence element 1 as the light source, the exposure device can be miniaturized, while by mounting such an exposure device on the forming apparatus, it is possible to provide a compact image forming apparatus.

By forming the light emitting layer 6 having the uniform thickness in the light emitting region LA of the organic electroluminescence element 1, the organic electroluminescence element 1 which can stably emit light can be realized. This advantage is particularly apparent in the organic electroluminescence element 1 which forms at least a portion of the light emitting layer 6 using the polymer material or the organic electroluminescence element 1 which forms at least a portion of the light emitting layer 6 using a material which is soluble in a solvent. In forming the organic electroluminescence element 1 using these materials, a method which forms a film in a state that the material is dissolved in a solvent without using a method such as vapor deposition. In this method, the irregularities of the thickness of the light emitting layer 6 caused by the non-uniform distribution of the vapor-deposited material during vapor deposition are larger than the irregularities of the thickness caused by the wettability with respect to a solution such as toluene and xylene which dissolves the organic light emitting material or a solution in which an organic light emitting material is dissolved a capillary phenomenon or surface tension attributed to a structured material and hence, the advantages of the present invention can be obtained in an outstanding manner.

Further with respect to the film forming method used for forming the light emitting layer, an ink jet method or the like forms a film by positively using surface tension or a water repellency of the pixel restricting portion 8, while a uniform-coating-type method such as a spin coat method, a gap method, a flood-print method (a uniform coating method using an ink jet) or a screen printing method uniformly apply a material for forming of the light emitting layer by coating whereby the advantages of the present invention appears in a more outstanding manner. These methods are frequently used for a monochromic light emitting layer which does not require the coating of the light emitting layer in a divided manner. The present invention is more advantageous when used in such methods or structures.

In the explanation described above, although the exposure device is explained on a premise that the organic electroluminescence element 1 is driven by a DOC power source. However, the organic electroluminescence element 1 may be driven either by an AC power source or by a pulse power source.

Here, in the embodiments 1 to 4, the explanation is made with respect to the constitution in which the pixel restricting portion 8 is formed by a vapor deposition method or by patterning a photosensitive resin using a photolithography method. In forming the pixel restricting portion 8 using such a material, when the thickness of the pixel restricting portion 8 is set to 50 nm or less, although the brightness distribution (light emission profile) in the light emitting region may be made uniform, in the region where the emission of light is originally prevented by the pixel restricting portion 8, due to the generation of fine pin holes or the like in the pixel restricting portion 8, leaking of current (so called “leaking”) is generated from the electrode (anode 3) through the pixel restricting portion 8 and, as a result, there arises influences such that the light emission occurs in a portion different from the original light emitting portion or the light emission efficiency is lowered due to the leaking of current.

However, in forming the pixel restricting portion 8 by a sputtering method or the like, for example, it is possible to form a dense film by patterning and hence, even when the film thickness of the pixel restricting portion 8 is set to a sufficiently small value, there is no possibility of the occurrence of leaking of current attributed to the formation of the fine pin holes or the like. Accordingly, by forming the pixel restricting portion 8 at least by the sputtering method, it is possible to set the thickness of the side of the pixel restricting portion which restrict the light emitting region to a value equal to or more than 20 nm and equal to or less than 100 nm.

Table 2 shows a result of an experiment in which the pixel restricting portion 8 is made of the above-mentioned material and the thickness of the pixel restricting portion 8 is changed.

TABLE 2

| | pixel restricting | | pixel restricting | |
|---|---|---|---|---|
| | portion formed by | | portion formed by | |
| | vapor deposition method | | sputtering method | |
| Thickness of | | Pin hole | | Pin hole |
| pixel restricting | Edge light | deter- | Edge light | deter- |
| portion [nm] | determination | mination | determination | mination |
| 10 | ∘ | x | ∘ | Δ |
| 20 | ∘ | Δ | ∘ | ∘ |
| 50 | ∘ | ∘ | ∘ | ∘ |
| 100 | ∘ | ∘ | ∘ | ∘ |
| 150 | Δ | ∘ | Δ | ∘ |
| 200 | x | ∘ | x | ∘ |

In Table 2, the edge light determination is performed such that, in the same manner as the edge light determination in Table 1, the edge light rate Lebb/Leba indicates a result of determination with respect to a rate of the edge light in the in-plane distribution O indicated in FIG. 17.

As shown in FIG. 2, even when the pixel restricting portion 8 is formed by either one of the vapor deposition method and the sputtering method, the rate of the edge light is decreased corresponding to the decrease of the thickness of the pixel restricting portion 8 and hence, by setting the thickness of the pixel restricting portion 8 to 100 nm or less, it is possible to reduce the rate of the edge light to a level of equal to or less than 1%. On the other hand, although the pin hole determination is made such that when the emission of light is clearly observed in the region other than the light emitting region where the light is originally radiated is determined to be bad (x), when the light emission in the region other than the light emitting region is slightly observed or the light emitting efficiency in the light emitting region is lowered, the determination is set as fair (Δ), and when the light emission occurs in a state other than the above-mentioned states, the determination is set to good (O). As shown in Table 2, the frequency of the occurrence of pin holes is reduced along with the increase of the thickness of the pixel restricting portion 8.

For example, when the pixel restricting portion 8 is formed by the vapor deposition method, it is possible to suppress the formation of the pin holes or the like by setting the film thickness of the pixel restricting portion 8 to 50 nm or more. Further, when the pixel restricting portion 8 is formed of a dense film by the sputtering method, it is possible to suppress the formation of the pin holes or the like by setting the thickness of the pixel restricting portion 8 to 20 nm or more. Further, in both cases, by setting the thickness of the pixel restricting portion 8 to 100 nm or less, no edge light is generated (that is, the uniformity of the light emission brightness distribution is favorable) and it is possible to allow only the desired region to emit light.

The organic electroluminescence element of the present invention and the exposure device or the image forming device using the organic electroluminescence element are available in various kinds of devices and apparatuses which are required to obtain the uniform light emission brightness or the stable light emission for a long period in the light emitting region LA of the organic electroluminescence element. For example, the electroluminescence element is applicable to a photocopier, a multi-function printer, a printer, a facsimile or the like. Further, since the organic electroluminescence element can obtain three primary colors of red, green and blue by selecting the organic light emitting materials, with the use of the exposure devices which perform the exposure using respective colors of R, G, and B, for example, it is also possible to apply the organic electroluminescence element of the present invention to the image forming apparatus which directly exposes the printing paper.

1. An organic electroluminescence element comprising:
an anode to which holes are injected;
a light emitting layer;
a cathode to which electrons are injected; and
a pixel restricting portion which restricts a light emitting region of the light emitting layer by controlling the injection of at least one of the holes and the electrons, wherein
a thickness of an end portion of the pixel restricting portion at least on a side which restricts the light emitting region is set to a value equal to or more than 20 nm and equal to or less than 100 nm.

2. An organic electroluminescence element comprising:
an anode to which holes are injected;
a light emitting layer;
a cathode to which electrons are injected; and
a pixel restricting portion which restricts a light emitting region of the light emitting layer by controlling the injection of at least one of the holes and the electrons, wherein
a thickness of an end portion of the pixel restricting portion at least on a side which restricts the light emitting region is set to a value equal to or more than 50 nm and equal to or less than 100 nm.

3. The organic electroluminescence element according to claim 1, wherein the pixel restricting portion is made of any one selected from a group consisting of silicon nitride, aluminum nitride, silicon oxide and aluminum oxide.

4. The organic electroluminescence element according to claim 1, wherein the pixel restricting portion is made of a metal material.

5. The organic electroluminescence element according to claim 4, wherein assuming a work function of the pixel restricting portion as W_{F1} and a work function of the anode as W_{F2}, the pixel restricting portion is made of the metal material which satisfies a relationship 2.0 [ev]<W_{F1}<W_{F2}.

6. The organic electroluminescence element according to claim 1, wherein the pixel restricting portion has a thickness thereof at portions other than the end portion set larger than the thickness at the end portion.

7. The organic electroluminescence element according to claim 6, wherein the pixel restricting portion is made of a material which prevents at least light having a light emitting wavelength radiated from the light emitting layer from passing therethrough.

8. The organic electroluminescence element according to claim 1, wherein the pixel restricting portion is formed by a sputtering method.

9. An organic electroluminescence element comprising:
an anode to which holes are injected;
a light emitting layer;
a cathode to which electrons are injected; and
a pixel restricting portion which is formed of a plurality of layers and restricts a light emitting region of the light emitting layer by controlling the injection of at least one of the holes and the electrons, wherein
a thickness of an end portion of the pixel restricting portion at least on a side which restricts the light emitting region is set to a value equal to or more than 20 nm and equal to or less than 100 nm.

10. An organic electroluminescence element comprising:
an anode to which holes are injected;
a light emitting layer;
a cathode to which electrons are injected; and
a pixel restricting portion which is formed of a plurality of layers and restricts a light emitting region of the light emitting layer by controlling the injection of at least one of the holes and the electrons, wherein
a thickness of an end portion of the pixel restricting portion at least on a side which restricts the light emitting region is set to a value equal to or more than 50 nm and equal to or less than 100 nm.

11. An organic electroluminescence element according to claim 9, wherein the pixel restricting portion is constituted of a first pixel restricting portion which is formed in contact with the anode or the cathode and a second pixel restricting portion which is formed in contact with the first pixel restricting portion and covers a portion of the anode or the cathode, and the light emitting region is restricted by the second pixel restricting portion.

12. An organic electroluminescence element according to claim 9, wherein the pixel restricting portion is constituted of a second pixel restricting portion which is formed in contact with the anode or the cathode and a first pixel restricting portion which is in contact with the second pixel restricting portion and covers a portion of the second pixel restricting portion, and the light emitting region is restricted by the second pixel restricting portion.

13. The organic electroluminescence element according to claim 11, wherein at least one of the first pixel restricting portion and the second pixel restricting portion is made of a material which prevents at least light having a light emitting wavelength radiated from the light emitting layer from passing therethrough.

14. The organic electroluminescence element according to claim 9, wherein at least one layer out of the pixel restricting portion formed of the plurality of layers is formed by a sputtering method.

15. An organic electroluminescence element comprising:
an anode to which holes are injected;
a light emitting layer;
a cathode to which electrons are injected; and
a pixel restricting portion which restricts a light emitting region of the light emitting layer by controlling the injection of at least one of the holes and the electrons, wherein
a thickness of an end portion of the pixel restricting portion at least on a side which restricts the light emitting region is set to a value which is twice or less larger than a thickness of the light emitting layer.

16. The organic electroluminescence element according to claim 15, wherein the thickness of the pixel restricting portion is set to a value equal to or more than 20 nm.

17. The organic electroluminescence element according to claim 15, wherein the thickness of the pixel restricting portion is set to a value equal to or more than 50 nm.

18. The organic electroluminescence element according to claim 16, wherein the pixel restricting portion is formed by a sputtering method.

19. An exposure device being characterized in that the organic electroluminescence elements described in claim 1 are arranged in a row, and the turning on and off of the organic electroluminescence elements are controlled individually.

20. An image forming apparatus comprising at least:
the exposure device described in claim 19;
a photoconductor on which an electrostatic latent image is formed by the exposure device; and
a developing means which visualizes the electrostatic latent image formed on the photoconductor.
